(19) United States
(12) Patent Application Publication
(10) Pub. No.: US 2026/0310031 A1
(43) Pub. Date: Oct. 8, 2026

(54) SEMICONDUCTOR DEVICE, DISPLAY DEVICE, DISPLAY MODULE, AND ELECTRONIC DEVICE

(71) Applicant: SEMICONDUCTOR ENERGY LABORATORY CO., LTD., Atsugi-shi, Kanagawa-ken (JP)

(72) Inventors: Hajime KIMURA, Atsugi, Kanagawa (JP); Susumu KAWASHIMA, Atsugi, Kanagawa (JP)

(21) Appl. No.: 19/482,032

(22) PCT Filed: May 13, 2024
(86) PCT No.: PCT/IB2024/054605

§ 371 Date: Nov. 6, 2025

(30) Foreign Application Priority Data
May 19, 2023 (JP) 2023-082677

(51) Int. Cl. G02F 1/1368; G02F 1/1362; H10D 86/40; H10D 86/60

(52) U.S. Cl. CPC G02F 1/1368; G02F 1/136209; G02F 1/136227; H10D 86/451; H10D 86/60

(57) ABSTRACT

A novel semiconductor device that is highly convenient, useful, or reliable can be provided. The semiconductor device includes a first functional layer, a second functional layer, and a first conductive layer. The second functional layer overlaps with the first functional layer and includes a functional element. The functional element includes a first electrode. The first functional layer includes a first layer, a spacer, and a transistor, and is sandwiched between the second functional layer and the spacer. The first layer includes a first opening portion and has an insulating property. The spacer includes a first plane, a second plane, a third plane, and a second opening portion. The first plane, the second plane, and the third plane each have an insulating property. The second plane faces the first plane, and the second plane is positioned closer to the first layer than the first plane is. The third plane connects the first plane and the second plane to each other and is positioned at the side surface of the second opening portion. The transistor includes a second electrode, a third electrode, a fourth electrode, a semiconductor layer, and an insulating layer. The first conductive layer electrically connects the third electrode and the first electrode to each other through the first opening portion.

### TECHNICAL FIELD

One embodiment of the present invention relates to a semiconductor device, a display device, a display module, and an electronic device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, more specific examples of the technical field of one embodiment of the present invention disclosed in this specification include a semiconductor device, a display device, a light-emitting apparatus, a power storage device, a memory device, a driving method thereof, and a manufacturing method thereof.

### BACKGROUND ART

An example of display devices is a liquid crystal display device including a liquid crystal device as a display element. For example, an active matrix liquid crystal display device in which pixel electrodes are arranged in a matrix and a switching element is connected to each of the pixel electrodes is used for various devices such as a smartphone, a tablet terminal, a monitor device, a television device, and digital signage.

It is known that liquid crystal display devices are classified into two major types: transmissive type and reflective type. A liquid crystal display device can display brighter images as the effective light-emitting area ratio (also referred to as an aperture ratio) of a pixel is higher, which also leads to a reduction in power consumption; thus, an improvement in aperture ratio is required.

For example, an active matrix liquid crystal display device in which transistors including a metal oxide in channel formation regions are used as switching elements connected to respective pixel electrodes is known. Patent Document 1 discloses a liquid crystal display device in which a transistor including metal oxide in its channel formation region is used to improve the aperture ratio.

### REFERENCE

### Patent Document

[Patent Document 1] Japanese Published Patent Application No. 2018-189938

### SUMMARY OF THE INVENTION

### Problems to be Solved by the Invention

As described above, various inventions have been disclosed in the prior art documents; however, they still have many issues with their convenience, usefulness, or reliability, and are not yet satisfactory. In view of the above, an object of one embodiment of the present invention is to provide a novel semiconductor device that is highly convenient, useful, or reliable. Another object is to provide a novel display device that is highly convenient, useful, or reliable. Another object is to provide a novel display module that is highly convenient, useful, or reliable. Another object is to provide a novel electronic device that is highly convenient, useful, or reliable. Another object is to provide a novel semiconductor device, a novel display device, a novel display module, or a novel electronic device.

Note that the description of these objects does not preclude the existence of other objects. One embodiment of the present invention does not necessarily achieve all these objects. Other objects will be apparent from the description of the specification, the drawings, the claims, and the like, and other objects can be derived from the description of the specification, the drawings, the claims, and the like.

### Means for Solving the Problems

(1) One embodiment of the present invention is a semiconductor device including a first functional layer, a second functional layer, and a first conductive layer.

The second functional layer overlaps with the first functional layer. The second functional layer includes a functional element. The functional element includes a first electrode.

The first functional layer includes a first layer, a spacer, and a transistor. The first layer is sandwiched between the second functional layer and the spacer. The first layer includes a first opening portion and has an insulating property.

The spacer includes a first plane, a second plane, a third plane, and a second opening portion. The first plane, the second plane, and the third plane each have an insulating property. The second plane faces the first plane. The second plane is positioned closer to the first layer than the first plane is. The third plane connects the first plane and the second plane to each other. The third plane is positioned at the side surface of the second opening portion.

The transistor includes a second electrode, a third electrode, a fourth electrode, a semiconductor layer, and an insulating layer. The second electrode includes a region in contact with the first plane and a region overlapping with the second opening portion. The third electrode includes a region in contact with the second plane, a third opening portion, and a fourth plane. The fourth plane is positioned at the side surface of the third opening portion. The third opening portion overlaps with the second opening portion. The fourth electrode includes a region facing the third plane. The insulating layer includes a region sandwiched between the third plane and the fourth electrode. The semiconductor layer includes a region sandwiched between the third plane and the insulating layer. The semiconductor layer is in contact with the second electrode in the second opening portion. The semiconductor layer is in contact with the third electrode on the fourth plane.

The first conductive layer electrically connects the third electrode and the first electrode to each other through the first opening portion.

(2) Another embodiment of the present invention is the above semiconductor device including a second conductive layer.

The second conductive layer is electrically connected to the second electrode. The second conductive layer has a light-blocking property. The first opening portion overlaps with the second conductive layer.

Thus, a step formed over the first opening portion can overlap with the second conductive layer. A flat region can be formed in a region not overlapping with the second conductive layer. In addition, an electrode of the functional element can be formed in the flat region. A flat region can be formed in the electrode. A layer containing a liquid crystal can be formed over the flat region of the electrode, for example. The second layer can be provided between the layer including a liquid crystal and a backlight, for example. Light can be blocked by the second conductive layer so that light of a backlight cannot reach a region in which alignment formed in a layer including a liquid crystal is disordered due to a step over the first opening portion. The aperture ratio of the liquid crystal device can be increased. The luminance of the display device can be increased. Power consumption can be reduced. As a result, a novel semiconductor device that is highly convenient, useful, or reliable can be provided.

(3) Another embodiment of the present invention is the above semiconductor device including a third conductive layer.

The first functional layer includes a second layer. The second layer is sandwiched between the first layer and the spacer. The second layer includes a fourth opening portion. The second layer has an insulating property.

The third conductive layer is sandwiched between the first layer and the second layer. The third conductive layer overlaps with the first opening portion and the fourth opening portion. The third conductive layer electrically connects the first conductive layer and the third electrode to each other. The third conductive layer has a light-transmitting property.

The third electrode has a light-transmitting property.

(4) One embodiment of the present invention is the above semiconductor device in which the first functional layer includes a fourth conductive layer.

The first layer is sandwiched between the fourth conductive layer and the third conductive layer. The fourth conductive layer has a light-transmitting property.

Thus, a capacitor can be formed using the fourth conductive layer, the third conductive layer, and the first layer. When the transistor is in the off state, the potential of the third conductive layer can be kept at a predetermined potential. In addition, the potential of the first electrode of the functional element can be kept at a predetermined potential. For example, an electric field with predetermined intensity can be continuously applied to the layer including a liquid crystal. As a result, a novel semiconductor device that is highly convenient, useful, or reliable can be provided.

(5) Another embodiment of the present invention is the above semiconductor device including a third conductive layer.

The first functional layer includes a second layer. The second layer is sandwiched between the first layer and the spacer. The second layer includes a fourth opening portion. The second layer has an insulating property.

The third conductive layer is sandwiched between the first layer and the second layer. The third conductive layer overlaps with the first opening portion and the fourth opening portion. The third conductive layer electrically connects the first conductive layer and the third electrode to each other. The third conductive layer has a light-transmitting property.

The second electrode has a light-blocking property. The first opening portion overlaps with the second electrode.

Thus, a step formed over the first opening portion can overlap with the second electrode of the transistor. A flat region can be formed in a region not overlapping with the second electrode. In addition, an electrode of the functional element can be formed in the flat region. A flat region can be formed in the electrode. A layer including a liquid crystal can be formed over the flat region of the electrode, for example. The second electrode can be provided between the layer including a liquid crystal and a backlight, for example. Light can be blocked by the second electrode so that light of the backlight cannot reach a region in which alignment formed in a layer including a liquid crystal is disordered due to the step over the first opening portion. The aperture ratio of the liquid crystal device can be increased. The luminance of the display device can be increased. Power consumption can be reduced. As a result, a novel semiconductor device that is highly convenient, useful, or reliable can be provided.

(6) Another embodiment of the present invention is the above semiconductor device including a third conductive layer and a fifth conductive layer.

The first functional layer includes a second layer. The second layer is sandwiched between the first layer and the spacer. The second layer includes a fourth opening portion. The second layer has an insulating property.

The third conductive layer is sandwiched between the first layer and the second layer. The third conductive layer overlaps with the first opening portion and the fourth opening portion. The third conductive layer electrically connects the first conductive layer and the third electrode to each other. The third conductive layer has a light-transmitting property.

The fifth conductive layer is electrically connected to the fourth electrode. The fifth conductive layer overlaps with the first opening portion. The fifth conductive layer has a light-blocking property.

Thus, a step formed over the first opening portion can overlap with the seventh conductive layer. A flat region can be formed in a region not overlapping with the seventh conductive layer. In addition, an electrode of the functional element can be formed in the flat region. A flat region can be formed in the electrode. A layer including a liquid crystal can be formed over the flat region of the electrode, for example. The seventh conductive layer can be provided between the layer including a liquid crystal and a backlight, for example. Light can be blocked by the seventh conductive layer so that light of the backlight cannot reach a region in which alignment formed in a layer including a liquid crystal is disordered due to the step over the first opening portion. The pixel aperture ratio of the liquid crystal device can be increased. The luminance of the display device can be increased. Power consumption can be reduced. As a result, a novel semiconductor device that is highly convenient, useful, or reliable can be provided.

(7) Another embodiment of the present invention is a display device in which the above functional element is a liquid crystal device.

(8) One embodiment of the present invention is a display module including the above display device and at least one of a connector and an integrated circuit.

(9) One embodiment of the present invention is an electronic device including the above display device and at least one of a battery, a camera, a speaker, and a microphone.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, a lighting device or the like may include the light-emitting apparatus.

### Effect of the Invention

One embodiment of the present invention can provide a novel semiconductor device that is highly convenient, useful, or reliable. Another embodiment of the present invention can provide a novel display device that is highly convenient, useful, or reliable. Another embodiment of the present invention can provide a novel display module that is highly convenient, useful, or reliable. Another embodiment of the present invention can provide a novel electronic device that is highly convenient, useful, or reliable. A novel semiconductor device can be provided. A novel display device can be provided. A novel display module can be provided. A novel electronic device can be provided.

Note that the description of these effects does not preclude the existence of other effects. One embodiment of the present invention does not need to have all these effects. Other effects will be apparent from and can be derived from the description of the specification, the drawings, the claims, and the like.

### BRIEF DESCRIPTION OF THE DRAWINGS

FIG. 1A to FIG. 1C are diagrams illustrating a structure of a semiconductor device according to an embodiment.

FIG. 2A and FIG. 2B are diagrams illustrating a structure of a semiconductor device of an embodiment.

FIG. 3 is a diagram illustrating a structure of a semiconductor device of an embodiment.

FIG. 4 is a diagram illustrating a structure of a semiconductor device of an embodiment.

FIG. 5A to FIG. 5C are diagrams illustrating a structure of a semiconductor device of an embodiment.

FIG. 6A and FIG. 6B are diagrams illustrating a structure of a semiconductor device of an embodiment.

FIG. 7 is a diagram illustrating a structure of a semiconductor device of an embodiment.

FIG. 8 is a diagram illustrating a structure of a semiconductor device of an embodiment.

FIG. 9A to FIG. 9C are diagrams illustrating a structure of a semiconductor device of an embodiment.

FIG. 10A and FIG. 10B are diagrams illustrating a structure of a semiconductor device of an embodiment.

FIG. 11 is a diagram illustrating a structure of a semiconductor device of an embodiment.

FIG. 12 is a diagram illustrating a structure of a semiconductor device of an embodiment.

FIG. 13A to FIG. 13C are diagrams illustrating a structure of a semiconductor device of an embodiment.

FIG. 14A and FIG. 14B are diagrams illustrating a structure of a semiconductor device of an embodiment.

FIG. 15 is a diagram illustrating a structure of a semiconductor device of an embodiment.

FIG. 16 is a diagram illustrating a structure of a semiconductor device of an embodiment.

FIG. 17 is a diagram illustrating a structure of a display device of an embodiment.

FIG. 18 is a diagram illustrating a structure of a display device of an embodiment.

FIG. 19 is a diagram illustrating a structure of a display device of an embodiment.

FIG. 20 is a diagram illustrating a structure of a display device of an embodiment.

FIG. 21 is a diagram illustrating a structure of a display device of an embodiment.

FIG. 22A to FIG. 22D are diagrams illustrating a structure of a transistor of an embodiment.

FIG. 23A to FIG. 23F are diagrams illustrating structures of a transistor of an embodiment.

FIG. 24A and FIG. 24B are diagrams illustrating a structure of a transistor of an embodiment.

FIG. 25A and FIG. 25B are diagrams illustrating a structure of a transistor of an embodiment.

FIG. 26A to FIG. 26C are diagrams illustrating structures of a display device of an embodiment.

FIG. 27A to FIG. 27D are diagrams illustrating driving methods of a display device of an embodiment.

FIG. 28 is a diagram illustrating a structure of a display device of an embodiment.

FIG. 29A to FIG. 29C are diagrams illustrating structures of a display module of an embodiment.

FIG. 30A to FIG. 30F are diagrams illustrating structures of electronic devices of an embodiment.

### MODE FOR CARRYING OUT THE INVENTION

The semiconductor device of one embodiment of the present invention includes a first functional layer, a second functional layer, and a first conductive layer. The second functional layer overlaps with the first functional layer and includes a functional element. The functional element includes a first electrode. The first functional layer includes a first layer, a spacer, and a transistor, and is sandwiched between the second functional layer and the spacer. The first layer includes a first opening portion, and the first layer has an insulating property. The spacer includes a first plane, a second plane, a third plane, and a second opening portion. The first plane, the second plane, and the third plane each have an insulating property. The second plane faces the first plane, and the second plane is positioned closer to the first layer than the first plane is. The third plane connects the first plane and the second plane to each other and is positioned at the side surface of the second opening portion. The transistor includes a second electrode, a third electrode, a fourth electrode, a semiconductor layer, and an insulating layer. The second electrode includes a region in contact with the first plane and a region overlapping with the second opening portion. The third electrode includes a region in contact with the second plane, a third opening portion, and a fourth plane. The fourth plane is positioned at the side surface of the third opening portion. The third opening portion overlaps with the second opening portion. The fourth electrode includes a region facing the third plane. The insulating layer includes a region sandwiched between the third plane and the fourth electrode. The semiconductor layer includes a region sandwiched between the third plane and the insulating layer. The semiconductor layer is in contact with the second electrode in the second opening portion. The semiconductor layer is in contact with the third electrode on the fourth plane. The first conductive layer electrically connects the third electrode and the first electrode to each other through the first opening portion.

Thus, a step formed over the first opening portion can overlap with the second conductive layer. A flat region can be formed in a region not overlapping with the second conductive layer. In addition, an electrode of the functional element can be formed in the flat region. A flat region can be formed in the electrode. A layer containing a liquid crystal can be formed over the flat region of the electrode, for example. The second layer can be provided between the layer including a liquid crystal and a backlight, for example. Light can be blocked by the second conductive layer so that light of the backlight cannot reach a region in which alignment formed in a layer including a liquid crystal is disordered due to the step over the first opening portion. The aperture ratio of the liquid crystal device can be increased. The luminance of the display device can be increased. Power consumption can be reduced. As a result, a novel semiconductor device that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

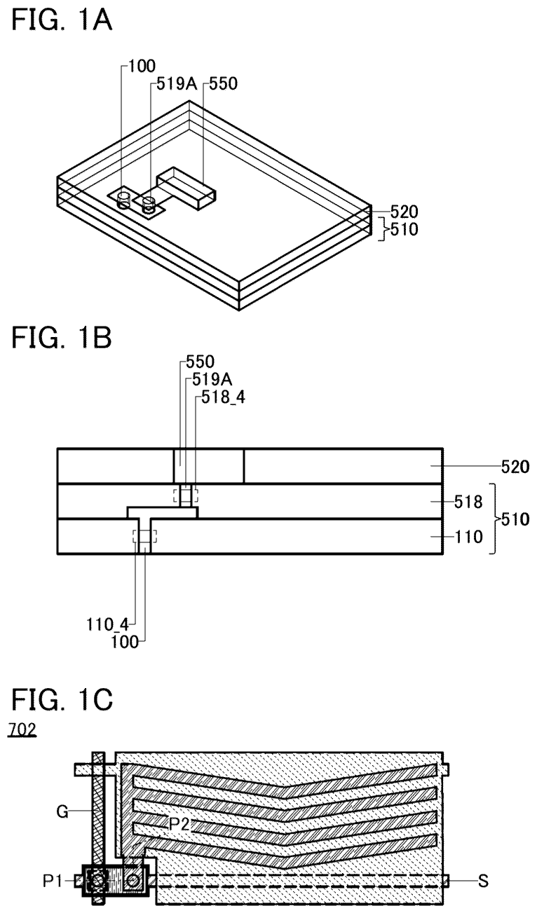

In this embodiment, a structure of a semiconductor device of one embodiment of the present invention will be described with reference to FIG. 1 to FIG. 16.

FIG. 1A is a perspective view schematically illustrating a structure of a semiconductor device of one embodiment of the present invention, and FIG. 1B is a cross-sectional view schematically illustrating the structure of the semiconductor device of one embodiment of the present invention. FIG. 1C is a top view illustrating an example of the semiconductor device of one embodiment of the present invention.

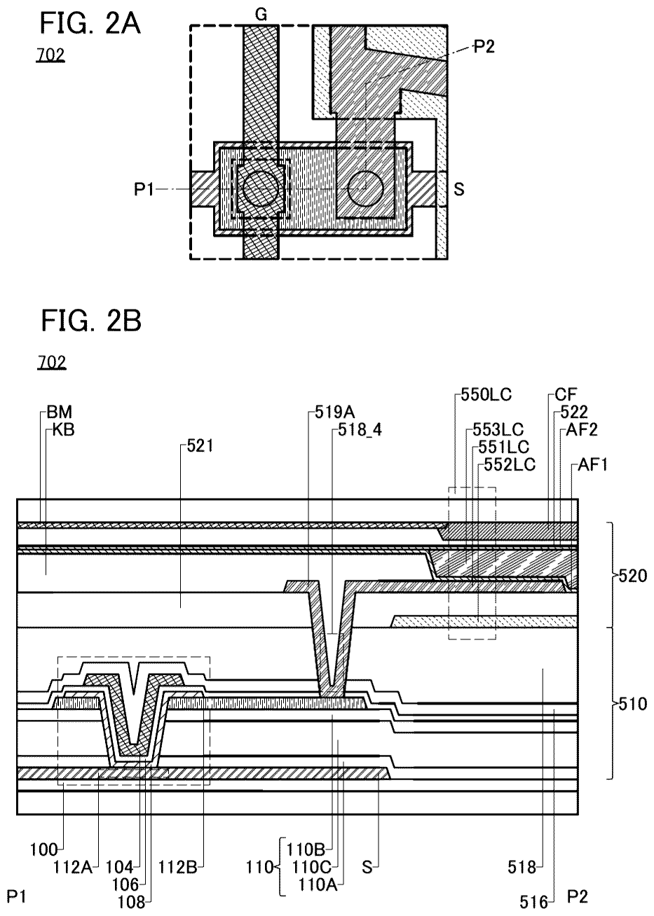

FIG. 2A is a front view illustrating part of the semiconductor device of one embodiment of the present invention illustrated in FIG. 1C, and FIG. 2B is a cross-sectional view taken along the section line P1-P2 in FIG. 2A.

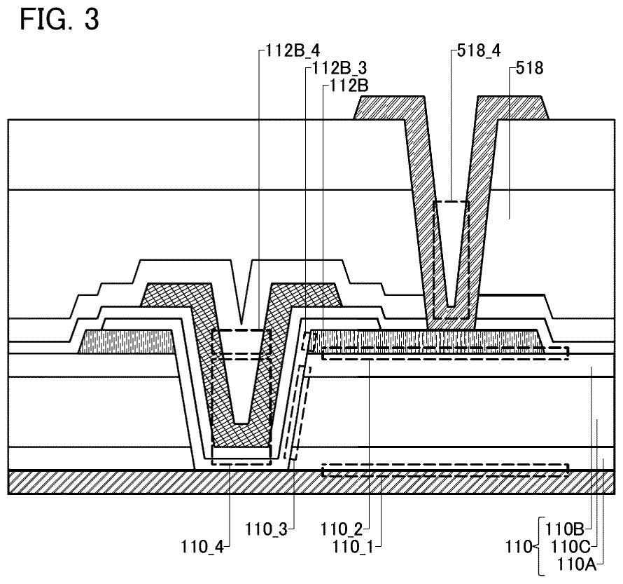

FIG. 3 is a diagram illustrating part of the structure illustrated in FIG. 2B in detail. Note that to avoid complexity of the drawing, a hatching pattern is omitted for some components.

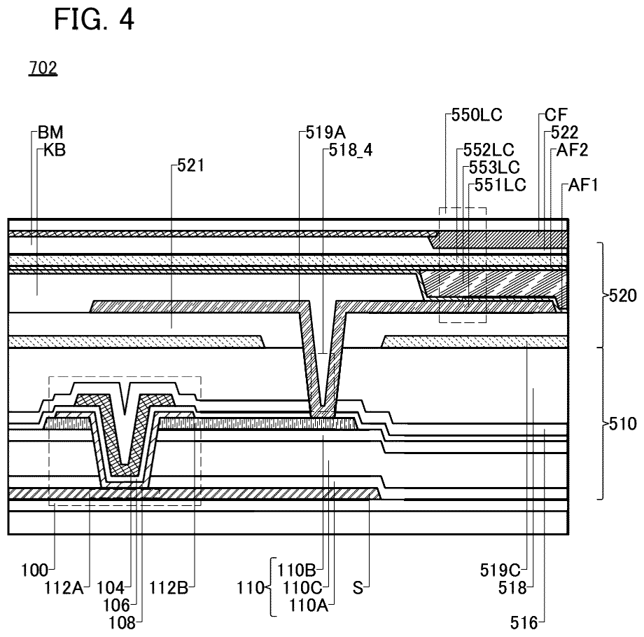

FIG. 4 is a cross-sectional view illustrating a structure of the semiconductor device of one embodiment of the present invention that is different from the semiconductor device illustrated in FIG. 2B.

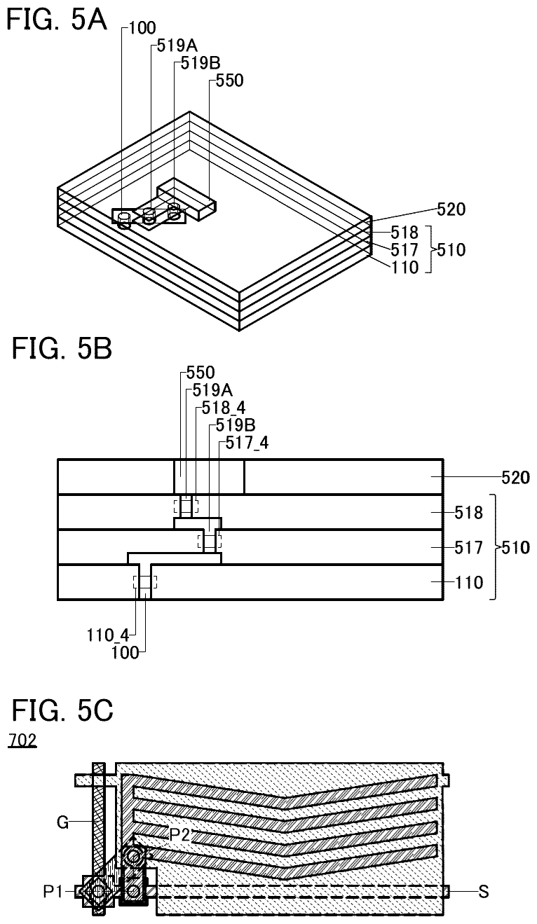

FIG. 5A is a perspective view schematically illustrating a structure of the semiconductor device of one embodiment of the present invention, and FIG. 5B is a cross-sectional view schematically illustrating the structure of the semiconductor device of one embodiment of the present invention. FIG. 5C is a top view illustrating an example of the semiconductor device of one embodiment of the present invention.

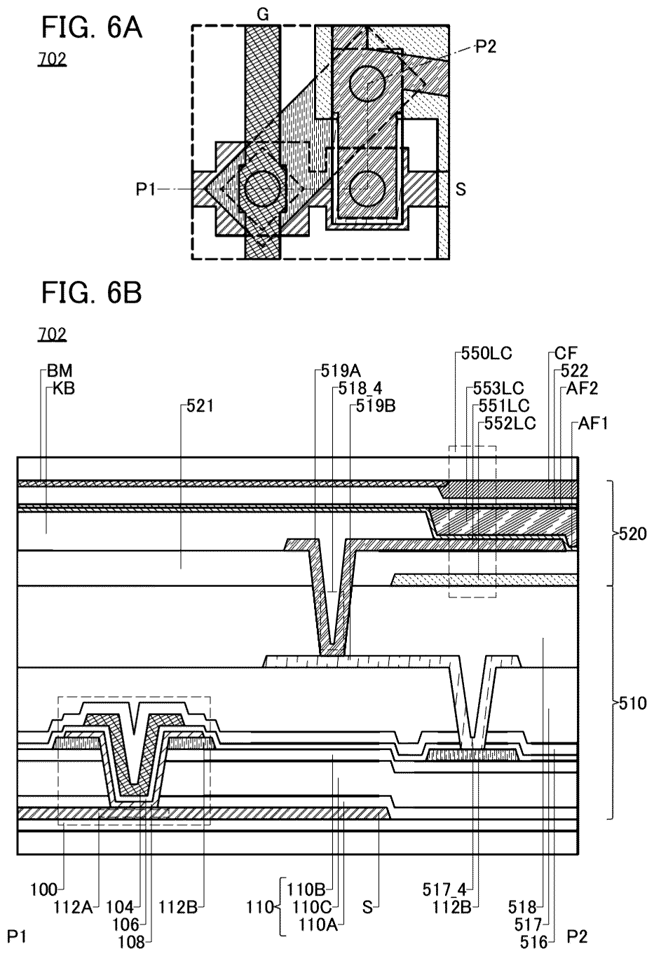

FIG. 6A is a front view illustrating part of the semiconductor device of one embodiment of the present invention illustrated in FIG. 5C, and FIG. 6B is a cross-sectional view taken along the section line P1-P2 in FIG. 6A.

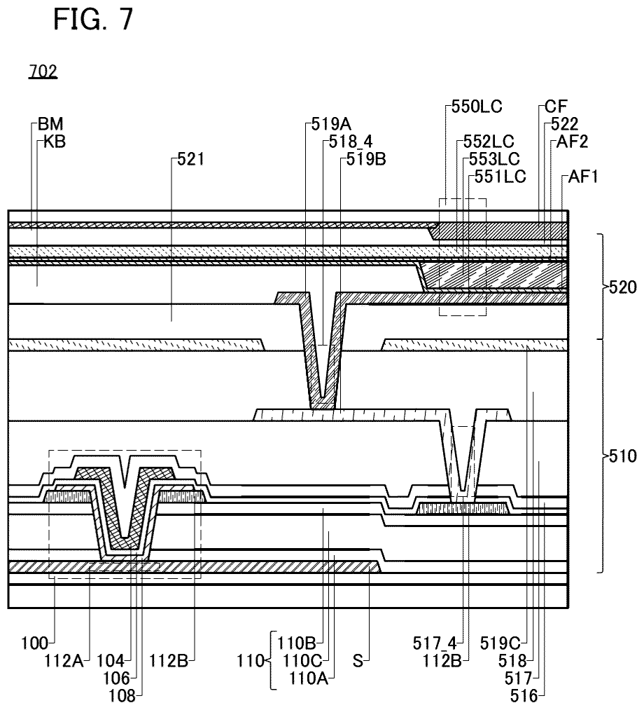

FIG. 7 is a cross-sectional view illustrating a structure of the semiconductor device of one embodiment of the present invention that is different from the semiconductor device illustrated in FIG. 6B.

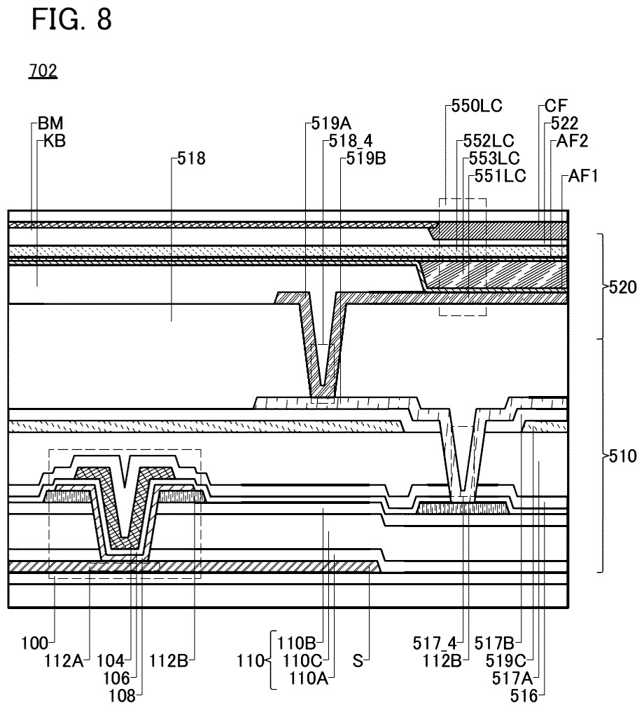

FIG. 8 is a cross-sectional view illustrating a structure of the semiconductor device of one embodiment of the present invention that is different from the semiconductor device illustrated in FIG. 7.

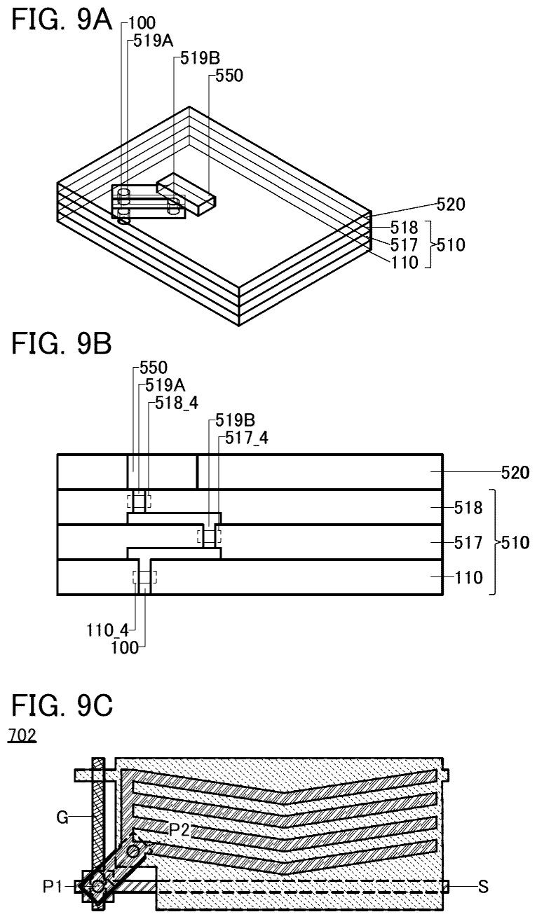

FIG. 9A is a perspective view schematically illustrating a structure of the semiconductor device of one embodiment of the present invention, and FIG. 9B is a cross-sectional view schematically illustrating the structure of the semiconductor device of one embodiment of the present invention. FIG. 9C is a top view illustrating an example of the semiconductor device of one embodiment of the present invention.

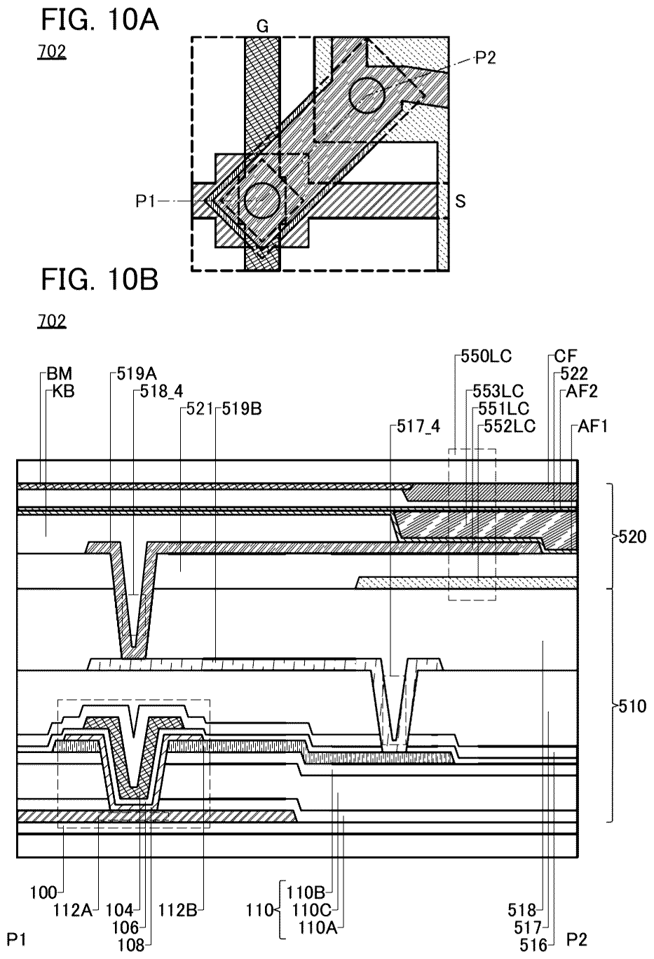

FIG. 10A is a front view illustrating part of the semiconductor device of one embodiment of the present invention illustrated in FIG. 9C, and FIG. 10B is a cross-sectional view taken along the section line P1-P2 in FIG. 10A.

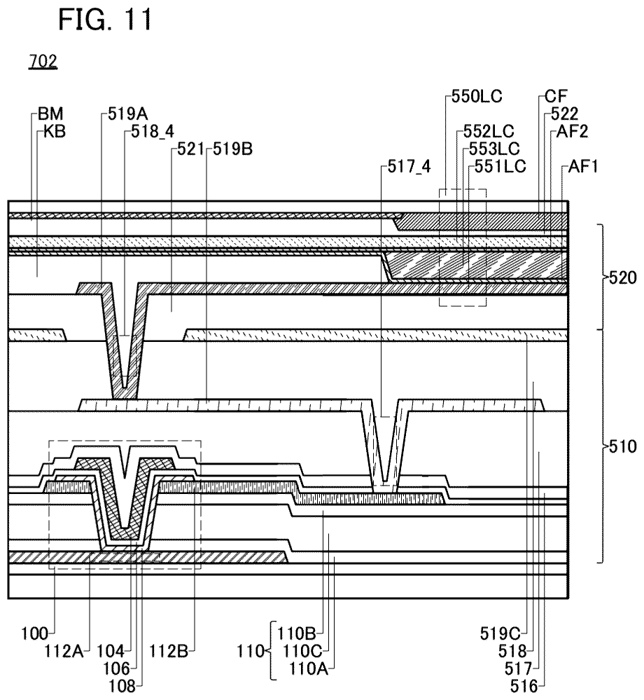

FIG. 11 is a cross-sectional view illustrating a structure of the semiconductor device of one embodiment of the present invention that is different from the semiconductor device illustrated in FIG. 10B.

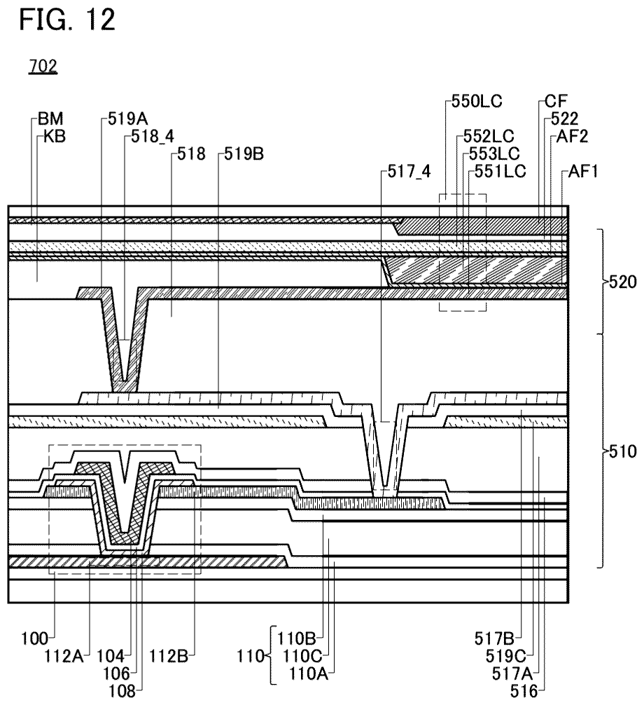

FIG. 12 is a cross-sectional view illustrating a structure of the semiconductor device of one embodiment of the present invention that is different from the semiconductor device illustrated in FIG. 11.

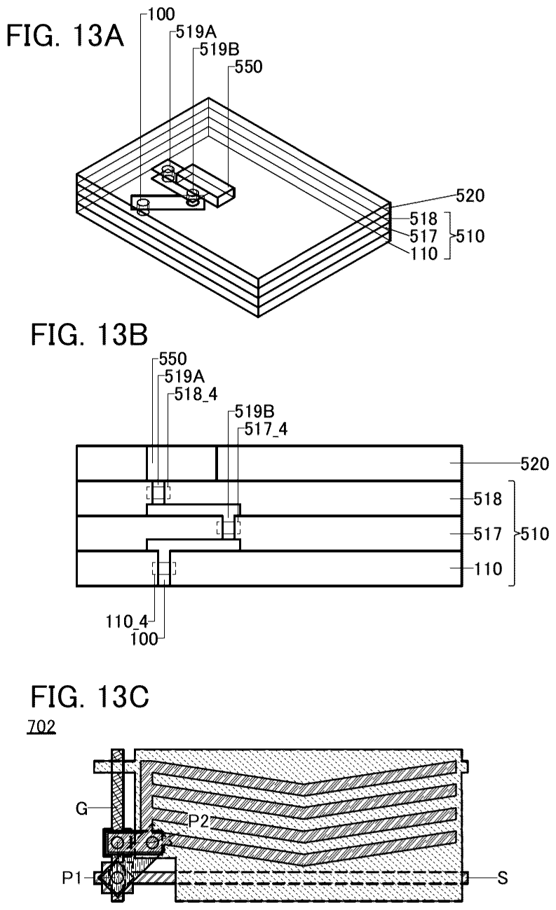

FIG. 13A is a perspective view schematically illustrating a structure of the semiconductor device of one embodiment of the present invention, and FIG. 13B is a cross-sectional view schematically illustrating the structure of the semiconductor device of one embodiment of the present invention. FIG. 13C is a top view illustrating an example of the semiconductor device of one embodiment of the present invention.

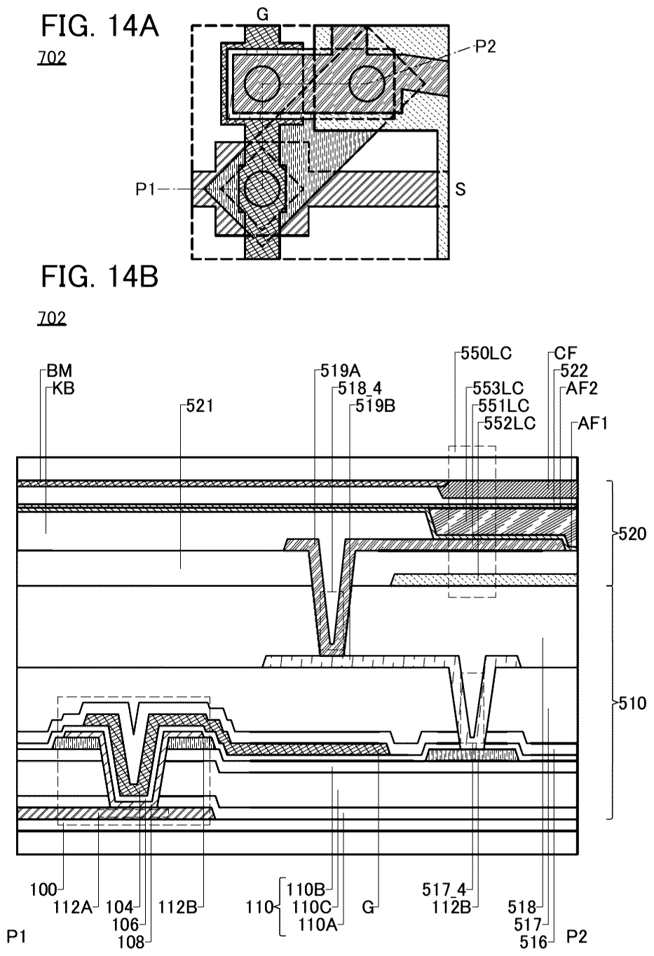

FIG. 14A is a front view illustrating part of the semiconductor device of one embodiment of the present invention illustrated in FIG. 13C, and FIG. 14B is a cross-sectional view taken along the section line P1-P2 in FIG. 14A.

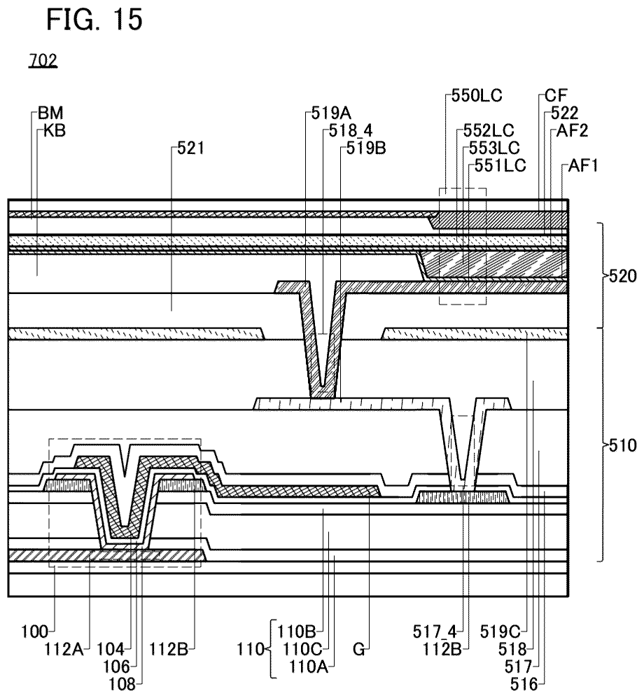

FIG. 15 is a cross-sectional view illustrating a structure of the semiconductor device of one embodiment of the present invention that is different from the semiconductor device illustrated in FIG. 14B.

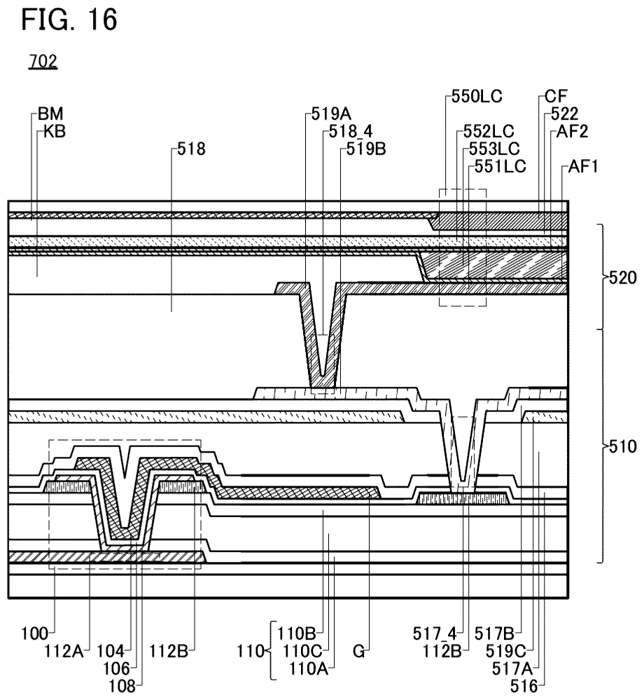

FIG. 16 is a cross-sectional view illustrating a structure of the semiconductor device of one embodiment of the present invention that is different from the semiconductor device illustrated in FIG. 15.

### Structure Example 1 of Semiconductor Device

One embodiment of the present invention is a semiconductor device including a functional layer 510, a functional layer 520, and a conductive layer 519A (see FIG. 1A).

### Structure Example 1 of Functional Layer 520

The functional layer 520 overlaps with the functional layer 510, and the functional layer 520 includes a functional element 550 (see FIG. 1A and FIG. 1B).

### Structure Example of Functional Element 550

For example, a liquid crystal device 550LC can be used as the functional element 550 (see FIG. 1C, FIG. 2B, or FIG. 4). The liquid crystal device 550LC includes an electrode 551LC. The liquid crystal device 550LC includes an electrode 552LC and a layer 553LC including a liquid crystal. The electrode 552LC is positioned so that an electric field which controls the alignment of the liquid crystal material can be generated between the electrode 552LC and the electrode 551LC. Note that without being limited to the liquid crystal device, a variety of functional elements can be used for the semiconductor device of one embodiment of the present invention. For example, a light-emitting device, a photoelectric conversion device, a memory device, or the like can be used, so that a flat region of the electrode can be effectively utilized.

For example, a comb-like shape can be employed for the electrode 551LC, and the electrode 552LC can be placed so that a horizontal electric field or a fringe electric field can be formed between the electrode 551LC and the electrode 552LC (see FIG. 1C and FIG. 2B). Note that the electrode 551LC is sandwiched between the layer 553LC including a liquid crystal and the electrode 552LC.

For example, the electrode 551LC can be provided so that a vertical electric field can be formed between the electrode 551LC and the electrode 552LC (see FIG. 4). Note that the layer 553LC including a liquid crystal is sandwiched between the electrode 551LC and the electrode 552LC.

The liquid crystal device 550LC includes an alignment film AF1 and an alignment film AF2. The alignment film AF1 is sandwiched between the layer 553LC including a liquid crystal and the electrode 551LC, and the layer 553LC is sandwiched between the alignment film AF2 and the alignment film AF1.

For example, a transmissive liquid crystal device employing a vertical alignment (VA) mode can be used as the liquid crystal device 550LC. As the vertical alignment mode, an MVA (Multi-Domain Vertical Alignment) mode, a PVA (Patterned Vertical Alignment) mode, an ASV (Advanced Super View) mode, and the like can be used.

The operation mode is not limited to the VA mode, and a liquid crystal device that operates in a variety of modes can be used as the liquid crystal device 550LC. The liquid crystal device 550LC can employ, for example, an FFS mode, a TN (Twisted Nematic) mode, an IPS mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like.

Here, the liquid crystal device controls transmission and non-transmission of light by utilizing polarized light and an optical modulation action of a liquid crystal. The optical modulation action of the liquid crystal is controlled by an electric field applied to the liquid crystal (including a horizontal electric field, a vertical electric field, and an oblique electric field). As a liquid crystal that can be used for the liquid crystal device, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, and the like can be used. These liquid crystal materials exhibit a cholesteric phase, a smectic phase, a cubic phase, a chiral nematic phase, an isotropic phase, or the like depending on conditions. As the liquid crystal material, either a positive liquid crystal or a negative liquid crystal may be used, and an appropriate liquid crystal material can be used depending on the mode or design to be used.

### Structure Example 2 of Functional Layer 520

The functional layer 520 includes a light-blocking film BM, a coloring layer CF, a layer 522, and a layer KB. The light-blocking film BM has an opening portion, and the coloring layer CF overlaps with the opening portion in the light-blocking film BM. The layer 522 is sandwiched between the coloring layer CF and the layer 553LC including a liquid crystal and has an insulating property. The layer KB is positioned between an opening portion 518_4 and the light-blocking film BM, and the layer KB controls the thickness of the layer 553LC including a liquid crystal. The functional layer 520 includes a layer 521. The layer 521 is sandwiched between the layer 553LC including a liquid crystal and the functional layer 510.

### Structure Example 1 of Functional Layer 510

The functional layer 510 has a layer 518, a spacer 110, and a transistor 100 (see FIG. 2B). The functional layer 510 includes a layer 516.

### Structure Example of Layer 518 and Layer 516

The layer 518 is sandwiched between the functional layer 520 and the spacer 110. The layer 518 includes the opening portion 518_4 and has an insulating property. The layer 516 is sandwiched between the layer 518 and the spacer 110 and overlaps with the transistor 100.

An insulating inorganic material, an insulating organic material, or an insulating composite material containing an inorganic material and an organic material, for example, can be used for the layer 518.

Specifically, an inorganic oxide, an inorganic nitride, an inorganic oxynitride, or the like can be used for the layer 518. Alternatively, a layered material in which two or more selected from an inorganic oxide, an inorganic nitride, an inorganic oxynitride, or the like are stacked can be used for the layer 518.

Specifically, silicon oxide, silicon nitride, silicon oxynitride, aluminum oxide, or the like can be used for the layer 518. Note that a silicon nitride film is a dense film and has an excellent function of inhibiting diffusion of impurities. A film having an excellent function of inhibiting diffusion of impurities can be suitably used for the layer 516. This can inhibit diffusion of impurities, which degrade the operation characteristics of the transistor 100, from the outside into the inside of the transistor 100 can be inhibited.

For example, polyester, polyolefin, polyamide, polyimide, polycarbonate, polysiloxane, an acrylic resin, or the like can be used for the layer 518. A photosensitive material may be used. Polyimide is excellent in the following properties compared with other organic materials: thermal stability, an insulating property, toughness, a low dielectric constant, a low coefficient of thermal expansion, and a high chemical resistance, and the like.

When the layer 518 is formed over the base, the layer 518 can reduce a level difference due to the structure of the base.

### Structure Example of Spacer 110

The spacer 110 includes a plane 110_1, a plane 110_2, a plane 110_3, and an opening portion 110_4 (see FIG. 3). The plane 110_1, the plane 110_2, and the plane 110_3 each have an insulating property.

The plane 110_2 faces the plane 110_1, and the plane 110_2 is positioned closer to the layer 518 than the plane 110_1 is.

For example, a structure in which a layer 110A, a layer 110B, and a layer 110C are stacked can be used as the spacer 110. In the case where the layer 110C is positioned between the layer 110A and the layer 110B, for example, the plane 110_1 is formed with the layer 110A and the plane 110_2 is formed with the layer 110B.

The plane 110_3 connects the plane 110_1 and the plane 110_2 to each other, and the plane 110_3 is positioned on the side surface of the opening portion 110_4.

For example, in the case where the spacer 110 has a structure in which the layer 110A, the layer 110B, and the layer 110C are stacked, the plane 110_3 is formed with the side surface of the opening portion in the layer 110A, the side surface of the opening portion in the layer 110B, and the side surface of the opening portion in the layer 110C.

### Structure Example of Transistor 100

The transistor 100 includes an electrode 112A, an electrode 112B, an electrode 104, a semiconductor layer 108, and an insulating layer 106 (see FIG. 2B).

The electrode 112A includes a region in contact with the plane 110_1 and a region overlapping with the opening portion 110_4.

The electrode 112B includes an opening portion 112B_4, a plane 112B_3, and a region in contact with the plane 110_2. The plane 112B_3 is positioned at the side surface of the opening portion 112B_4, and the opening portion 112B_4 overlaps with the opening portion 110_4.

The electrode 104 includes a region facing the plane 110_3. The electrode 104 functions as a gate electrode of the transistor 100.

The insulating layer 106 includes a region sandwiched between the plane 110_3 and the electrode 104. The insulating layer 106 functions as a gate insulating film of the transistor 100.

The semiconductor layer 108 includes a region sandwiched between the plane 110_3 and the insulating layer 106. Note that the channel of the transistor 100 is formed in the semiconductor layer 108.

The semiconductor layer 108 is in contact with the electrode 112A in the opening portion 110_4, and the semiconductor layer 108 is in contact with the electrode 112B at the plane 112B_3. The electrode 112A functions as one of a source electrode and a drain electrode of the transistor 100, and the electrode 112B functions as the other of the source electrode and the drain electrode of the transistor 100. Note that a detailed structure that can be employed for the transistor 100 will be described in detail in Embodiment 3.

### Structure Example of Conductive Layer 519A

The conductive layer 519A electrically connects the electrode 112B and the electrode 551LC to each other through the opening portion 518_4.

For example, a conductive film is formed over the layer 518 in which the opening portion 518_4 is formed at a position overlapping with the electrode 112B, whereby the conductive film and the electrode 112B can be electrically connected to each other through the opening portion 518 4. Furthermore, the conductive film can be processed into a predetermined shape to form the conductive layer 519A and the electrode 551LC. In the case where the conductive layer 519A and the electrode 551LC are formed using the same conductive layer, the conductive layer 519A refers to a portion of the conductive layer which overlaps with the opening portion 518_4 in the layer 518, and the electrode 551LC refers to a portion of the conductive layer which overlaps with a flat region of the layer 518.

An inorganic conductive material, an organic conductive material, a metal, a conductive oxide, or the like can be used for the conductive layer 519A.

Specifically, a metal element selected from aluminum, gold, platinum, silver, copper, chromium, tantalum, titanium, molybdenum, tungsten, nickel, iron, cobalt, palladium, and manganese, or the like can be used for the conductive layer 519A. Alternatively, an alloy containing the above-described metal element, or the like can be used for the conductive layer 519A.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure of a titanium film, an aluminum film stacked over the titanium film, and a titanium film further formed thereover, or the like can be employed for the conductive layer 519A.

For example, a conductive oxide containing indium can be used for the conductive layer 519A. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used for the conductive layer 519A. Specifically, zinc oxide, zinc oxide to which gallium is added, zinc oxide to which aluminum is added, or the like can be used.

### Structure Example 2 of Semiconductor Device

The semiconductor device of one embodiment of the present invention includes a conductive layer S (see FIG. 1C and FIG. 2B).

### Structure Example of Conductive Layer S

The conductive layer S is electrically connected to the electrode 112A and has a light-blocking property. For example, a wiring for supplying a signal to the liquid crystal device 550LC can be used for the conductive layer S. Note that in the case where the conductive layer S and the electrode 112 A are formed using the same conductive layer, the electrode 112A refers to a portion of the conductive layer which overlaps with the opening portion 110_4 in the spacer 110, and the conductive layer S refers to a portion of the conductive layer which overlaps with the flat region in the spacer 110. A material that can be used for the conductive layer 519A can be used for the conductive layer S, and in particular, a metal or an alloy can be suitably used.

The opening portion 518_4 overlaps with the conductive layer S. In other words, the opening 518_4 overlaps with the electrode 112B and the conductive layer S.

Thus, a step formed over the opening portion 518_4 can overlap with the conductive layer S. A flat region can be formed in a region not overlapping with the conductive layer S. In addition, an electrode of the functional element 550 can be formed in the flat region. A flat region can be formed in the electrode. A layer including a liquid crystal can be formed over the flat region of the electrode, for example. The conductive layer S can be provided between the layer including a liquid crystal and a backlight, for example. Light can be blocked by the conductive layer S so that light of the backlight cannot reach a region in which alignment formed in a layer including a liquid crystal is disordered due to the step over the opening portion 518_4. The aperture ratio of the liquid crystal device can be increased. The luminance of the display device can be increased. Power consumption can be reduced. As a result, a novel semiconductor device that is highly convenient, useful, or reliable can be provided.

### Structure Example 3 of Semiconductor Device

The semiconductor device of one embodiment of the present invention includes a conductive layer 519B (see FIG. 5A and FIG. 5B). Note that the semiconductor device described with reference to FIG. 5A and FIG. 5B is different from the semiconductor device described with reference to FIG. 1A and FIG. 1B in that the conductive layer 519B is included and the functional layer 510 includes a layer 517.

### Structure Example 2 of Functional Layer 510

The functional layer 510 includes the layer 517. The layer 517 is sandwiched between the layer 518 and the spacer 110 (see FIG. 5A, FIG. 5B, and FIG. 6B).

### Structure Example 1 of Layer 517

The layer 517 includes an opening portion 517_4 and has an insulating property (see FIG. 6B). For example, a material that can be used for the layer 518 can be used for the layer 517.

### Structure Example 1 of Conductive Layer 519B

The conductive layer 519B is sandwiched between the layer 518 and the layer 517. For example, a material that can be used for the conductive layer 519A can be used for the conductive layer 519B.

The conductive layer 519B overlaps with the opening portion 518_4 and the opening portion 517_4. The conductive layer 519B electrically connects the conductive layer 519A and the electrode 112B to each other.

For example, a conductive film is formed over the layer 517 in which the opening portion 517_4 is formed at a position overlapping with the electrode 112B, whereby the conductive film and the electrode 112B can be electrically connected to each other through the opening portion 517_4. Furthermore, the conductive layer 519B can be formed by processing the conductive film into a predetermined shape.

For example, a conductive film is formed over the layer 518 in which the opening portion 518_4 is formed at a position overlapping with the conductive layer 519B, whereby the conductive film and the electrode 112B can be electrically connected to each other through the opening portion 518_4. Furthermore, the conductive film can be processed into a predetermined shape to form the conductive layer 519A and the electrode 551LC.

Note that the conductive layer 519B has a light-transmitting property, and the electrode 112B also has a light-transmitting property. Thus, the aperture ratio of the liquid crystal device can be increased, for example.

### Structure Example 4 of Semiconductor Device

The semiconductor device of one embodiment of the present invention includes a conductive layer 519C (see FIG. 7). Note that the semiconductor device described with reference to FIG. 7 is different from the semiconductor device described with reference to FIG. 5C, FIG. 6A, and FIG. 6B in that the functional layer 510 includes the layer 517 and the layer 553LC including a liquid crystal is sandwiched between the electrode 551LC and the electrode 552LC.

### Structure Example 3 of Functional Layer 510

The functional layer 510 includes the conductive layer 519C, and the layer 518 is sandwiched between the conductive layer 519C and the conductive layer 519B. Thus, a capacitor can be formed using the conductive layer 519C, the conductive layer 519B, and the layer 518. For example, a power supply potential or a ground potential can be supplied to the conductive layer 519C.

### Structure Example 1 of Conductive Layer 519C

The conductive layer 519C has a light-transmitting property. For example, a material that can be used for the conductive layer 519A can be used for the conductive layer 519C.

### Structure Example 5 of Semiconductor Device

The semiconductor device of one embodiment of the present invention includes the conductive layer 519C (see FIG. 8). Note that the semiconductor device described with reference to FIG. 8 is different from the semiconductor device described with reference to FIG. 7 in that the layer 517 includes a layer 517A and a layer 517B and the conductive layer 519C is sandwiched between the layer 517A and the layer 517B.

### Structure Example 4 of Functional Layer 510

The functional layer 510 includes the conductive layer 519C (see FIG. 8).

### Structure Example 2 of Layer 517

The layer 517 includes the layer 517A and the layer 517B. The layer 517B is sandwiched between the layer 518 and the layer 517A. For example, a material that can be used for the layer 518 can be used for the layer 517A and the layer 517B.

### Structure Example 2 of Conductive Layer 519C

The conductive layer 519C is sandwiched between the layer 517B and the layer 517A. The conductive layer 519C has a light-transmitting property. Thus, a capacitor can be formed using the conductive layer 519C, the conductive layer 519B, and the layer 517B. For example, a power supply potential or a ground potential can be supplied to the conductive layer 519C.

Thus, a capacitor can be formed using the conductive layer 519C, the conductive layer 519B, and the layer 518. When the transistor 100 is in a non-conduction state, the potential of the conductive layer 519B can be kept at a predetermined potential. In addition, the potential of the electrode of the functional element 550 can be kept at a predetermined potential. For example, an electric field with predetermined intensity can be continuously supplied to the layer including a liquid crystal. As a result, a novel semiconductor device that is highly convenient, useful, or reliable can be provided.

### Structure Example 6 of Semiconductor Device

The semiconductor device of one embodiment of the present invention includes the conductive layer 519B (see FIG. 9A and FIG. 9B). Note that the semiconductor device described with reference to FIG. 9A and FIG. 9B is different from the semiconductor device described with reference to FIG. 5A and FIG. 5B in that the opening portion 518_4 overlaps with the opening portion 110_4 in the spacer 110.

### Structure Example 5 of Functional Layer 510

The functional layer 510 includes the layer 517. The layer 517 is sandwiched between the layer 518 and the spacer 110 (see FIG. 9A, FIG. 9B, and FIG. 10B).

### Structure Example 3 of Layer 517

The layer 517 includes the opening portion 517_4 and has an insulating property (see FIG. 10B). For example, a material that can be used for the layer 518 can be used for the layer 517.

### Structure Example 2 of Conductive Layer 519B

The conductive layer 519B is sandwiched between the layer 518 and the layer 517. For example, a material that can be used for the conductive layer 519A can be used for the conductive layer 519B.

The conductive layer 519B overlaps with the opening portion 518_4 and the opening portion 517_4. The conductive layer 519B electrically connects the conductive layer 519A and the electrode 112B to each other.

For example, a conductive film is formed over the layer 517 in which the opening portion 517_4 is formed at a position overlapping with the electrode 112B, whereby the conductive film and the electrode 112B can be electrically connected to each other through the opening portion 517_4. Furthermore, the conductive layer 519B can be formed by processing the conductive film into a predetermined shape.

For example, a conductive film is formed over the layer 518 in which the opening portion 518_4 is formed at a position overlapping with the conductive layer 519B, whereby the conductive film and the electrode 112B can be electrically connected to each other through the opening portion 518_4. Furthermore, the conductive film can be processed into a predetermined shape to form the conductive layer 519A and the electrode 551LC.

Note that the conductive layer 519B has a light-transmitting property.

The electrode 112A has a light-blocking property, and the opening portion 518_4 overlaps with the electrode 112A.

### Structure Example 7 of Semiconductor Device

The semiconductor device of one embodiment of the present invention includes the conductive layer 519C (see FIG. 11). Note that the semiconductor device described with reference to FIG. 11 is different from the semiconductor device described with reference to FIG. 9C, FIG. 10A, and FIG. 10B in that the functional layer 510 includes the layer 517 and the layer 553LC including a liquid crystal is sandwiched between the electrode 551LC and the electrode 552LC.

### Structure Example 6 of Functional Layer 510

The functional layer 510 includes the conductive layer 519C, and the layer 518 is sandwiched between the conductive layer 519C and the conductive layer 519B (see FIG. 11). Thus, a capacitor can be formed using the conductive layer 519C, the conductive layer 519B, and the layer 518. For example, a power supply potential or a ground potential can be supplied to the conductive layer 519C.

### Structure Example 3 of Conductive Layer 519C

The conductive layer 519C has a light-transmitting property. For example, a material that can be used for the conductive layer 519A can be used for the conductive layer 519C.

### Structure Example 8 of Semiconductor Device

The semiconductor device of one embodiment of the present invention includes the conductive layer 519C (see FIG. 12). Note that the semiconductor device described with reference to FIG. 12 is different from the semiconductor device described with reference to FIG. 11 in that the layer 517 includes the layer 517A and the layer 517B and the conductive layer 519C is sandwiched between the layer 517A and the layer 517B.

### Structure Example 7of Functional Layer 510

The functional layer 510 includes the conductive layer 519C (see FIG. 12).

### Structure Example 4 of Layer 517

The layer 517 includes the layer 517A and the layer 517B. The layer 517B is sandwiched between the layer 518 and the layer 517A. For example, a material that can be used for the layer 518 can be used for the layer 517A and the layer 517B.

### Structure Example 4 of Conductive Layer 519C

The conductive layer 519C is sandwiched between the layer 517B and the layer 517A. The conductive layer 519C has a light-transmitting property. Thus, a capacitor can be formed using the conductive layer 519C, the conductive layer 519B, and the layer 517B. For example, a power supply potential or a ground potential can be supplied to the conductive layer 519C.

Thus, a step formed over the opening portion 518_4 can overlap with the electrode 112A of the transistor 100. A flat region can be formed in a region not overlapping with the electrode 112A. In addition, an electrode of the functional element 550 can be formed in the flat region. A flat region can be formed in the electrode. A layer including a liquid crystal can be formed over the flat region of the electrode, for example. The electrode 112A can be provided between the layer including a liquid crystal and a backlight, for example. Light can be blocked by the electrode 112A so that light of the backlight cannot reach a region in which alignment formed in a layer including a liquid crystal is disordered due to the step over the opening portion 518_4. The aperture ratio of the liquid crystal device can be increased. The luminance of the display device can be increased. Power consumption can be reduced. As a result, a novel semiconductor device that is highly convenient, useful, or reliable can be provided.

### Structure Example 9 of Semiconductor Device

The semiconductor device of one embodiment of the present invention includes the conductive layer 519B and a conductive layer G (see FIG. 13A, FIG. 13B, and FIG. 14B). Note that the semiconductor device described with reference to FIG. 13A and FIG. 13B is different from the semiconductor device described with reference to FIG. 9A and FIG. 9B in that the functional layer 510 includes the conductive layer G and the opening 518_4 overlaps with the conductive layer G.

### Structure Example 8 of Functional Layer 510

The functional layer 510 includes the layer 517. The layer 517 is sandwiched between the layer 518 and the spacer 110 (see FIG. 13A, FIG. 13B, and FIG. 14B).

### Structure Example 5 of Layer 517

The layer 517 includes the opening portion 517_4 and has an insulating property. For example, a material that can be used for the layer 518 can be used for the layer 517.

### Structure Example 3 of Conductive Layer 519B

The conductive layer 519B is sandwiched between the layer 518 and the layer 517. For example, a material that can be used for the conductive layer 519A can be used for the conductive layer 519B.

The conductive layer 519B overlaps with the opening portion 518_4 and the opening portion 517_4. The conductive layer 519B electrically connects the conductive layer 519A and the electrode 112B to each other.

For example, a conductive film is formed over the layer 517 in which the opening portion 517_4 is formed at a position overlapping with the electrode 112B, whereby the conductive film and the electrode 112B can be electrically connected to each other through the opening portion 517_4. Furthermore, the conductive layer 519B can be formed by processing the conductive film into a predetermined shape.

For example, a conductive film is formed over the layer 518 in which the opening portion 518_4 is formed at a position overlapping with the conductive layer 519B, whereby the conductive film and the electrode 112B can be electrically connected to each other through the opening portion 518_4. Furthermore, the conductive film can be processed into a predetermined shape to form the conductive layer 519A and the electrode 551LC.

Note that the conductive layer 519B has a light-transmitting property.

### Structure Example of Conductive Layer G

The conductive layer G is electrically connected to the electrode 104 and has a light-blocking property. For example, a wiring for supplying a control signal to the transistor 100 can be used for the conductive layer G.

The conductive layer G overlaps with the opening portion 518_4. In other words, the opening portion 518_4 overlaps with the conductive layer 519B and the conductive layer G.

### Structure Example 10 of Semiconductor Device

The semiconductor device of one embodiment of the present invention includes the conductive layer 519C (see FIG. 15). Note that the semiconductor device described with reference to FIG. 15 is different from the semiconductor device described with reference to FIG. 13C, FIG. 14A, and FIG. 14B in that the functional layer 510 includes the layer 517 and the layer 553LC including a liquid crystal is sandwiched between the electrode 551LC and the electrode 552LC.

### Structure Example 9 of Functional Layer 510

The functional layer 510 includes the conductive layer 519C, and the layer 518 is sandwiched between the conductive layer 519C and the conductive layer 519B (see FIG. 15). Thus, a capacitor can be formed using the conductive layer 519C, the conductive layer 519B, and the layer 518. For example, a power supply potential or a ground potential can be supplied to the conductive layer 519C.

### Structure Example 5 of Conductive Layer 519C

The conductive layer 519C has a light-transmitting property. For example, a material that can be used for the conductive layer 519A can be used for the conductive layer 519C.

### Structure Example 11 of Semiconductor Device

The semiconductor device of one embodiment of the present invention includes the conductive layer 519C (see FIG. 16). Note that the semiconductor device described with reference to FIG. 16 is different from the semiconductor device described with reference to FIG. 15 in that the layer 517 includes the layer 517A and the layer 517B and the conductive layer 519C is sandwiched between the layer 517A and the layer 517B.

### Structure Example 10 of Functional Layer 510

The functional layer 510 includes the conductive layer 519C (see FIG. 16).

### Structure Example 6 of Layer 517

The layer 517 includes the layer 517A and the layer 517B. The layer 517B is sandwiched between the layer 518 and the layer 517A. For example, a material that can be used for the layer 518 can be used for the layer 517A and the layer 517B.

### Structure Example 6 of Conductive Layer 519C

The conductive layer 519C is sandwiched between the layer 517B and the layer 517A. The conductive layer 519C has a light-transmitting property. Thus, a capacitor can be formed using the conductive layer 519C, the conductive layer 519B, and the layer 517B. For example, a power supply potential or a ground potential can be supplied to the conductive layer 519C.

Thus, a step formed over the opening portion 518_4 can overlap with the conductive layer G. A flat region can be formed in a region not overlapping with the conductive layer G. In addition, an electrode of the functional element 550 can be formed in the flat region. A flat region can be formed in the electrode. A layer including a liquid crystal can be formed over the flat region of the electrode, for example. The conductive layer G can be provided between the layer including a liquid crystal and a backlight, for example. Light can be blocked by the conductive layer G so that light of the backlight cannot reach a region in which alignment formed in a layer including a liquid crystal is disordered due to the step over the opening portion 518_4. The aperture ratio of the liquid crystal device can be increased. The luminance of the display device can be increased. Power consumption can be reduced. As a result, a novel semiconductor device that is highly convenient, useful, or reliable can be provided.

Note that this embodiment can be combined with any of the other embodiments in this specification as appropriate.

### Embodiment 2

In this embodiment, a structure example of a display device of one embodiment of the present invention will be described.

The display device of this embodiment can be a high-definition display device or a large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a tape carrier package (TCP) is attached to the display device and a module in which the display device is mounted with an integrated circuit (IC) by a chip on glass (COG) method, a chip on film (COF) method, or the like.

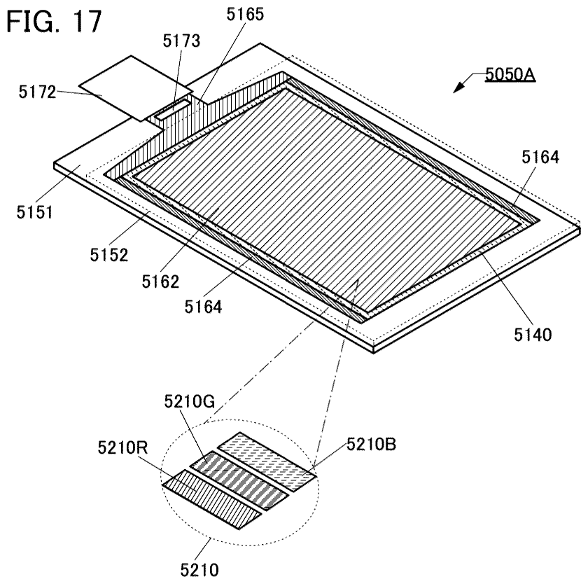

FIG. 17 is a perspective view of a display device 5050A.

In the display device 5050A, a substrate 5152 and a substrate 5151 are bonded to each other. In FIG. 17, the substrate 5152 is denoted by a dashed line.

The display device 5050A includes a display portion 5162, a connection portion 5140, a circuit portion 5164, a wiring 5165, and the like. FIG. 17 illustrates an example in which an IC 5173 and an FPC 5172 are mounted on the display device 5050A. Thus, the structure illustrated in FIG. 17 can be regarded as a display module including the display device 5050A, the IC, and the FPC.

The connection portion 5140 is provided outside the display portion 5162. The connection portion 5140 can be provided along one or more sides of the display portion 5162. The number of the connection portions 5140 can be one or more. FIG. 17 illustrates an example where the connection portion 5140 is provided to surround the four sides of the display portion. In the connection portion 5140, a common electrode of a display element is electrically connected to a conductive layer so that a potential can be supplied to the common electrode. Note that the connection portion 5140 is not necessarily provided if not needed, for example, in the case where the common electrode is provided on the substrate 5151 side.

The circuit portion 5164 includes a scan line driver circuit (also referred to as a gate driver), for example. The circuit portion 5164 may include both a scan line driver circuit and a signal line driver circuit (also referred to as a source driver).

The wiring 5165 has a function of supplying a signal and power to the display portion 5162 and the circuit portion 5164. The signal and power are input to the wiring 5165 from the outside through the FPC 5172 or from the IC 5173.

FIG. 17 illustrates an example in which the IC 5173 is provided on the substrate 5151 by a COG method, a COF method, or the like. An IC including one or both of a scan line driver circuit and a signal line driver circuit can be used as the IC 5173, for example. Note that the display device 5050A and the display module are not necessarily provided with an IC. The IC may be mounted on the FPC by a COF method or the like.

The vertical transistor of one embodiment of the present invention can be used for one or both of the display portion 5162 and the circuit portion 5164 of the display device 5050A, for example. The vertical transistor of one embodiment of the present invention can also be used for the IC 5173.

In the case where the vertical transistor of one embodiment of the present invention is used for a pixel circuit of the display device, the area occupied by the pixel circuit can be reduced and the display device can have a high resolution, for example. When the vertical transistor of one embodiment of the present invention is used for a driver circuit (e.g., one or both of a gate line driver circuit and a source line driver circuit) of the display device, the area occupied by the driver circuit can be reduced and the display device can have a narrow bezel, for example. Since the vertical transistor of one embodiment of the present invention has excellent electrical characteristics, a display device can have increased reliability by using the transistor.

The display portion 5162 of the display device 5050A is a region where an image is to be displayed, and includes a plurality of pixels 5210 that are periodically arranged. FIG. 17 illustrates an enlarged view of one of the pixels 5210.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 5210 illustrated in FIG. 17 includes a subpixel 5210R that emits red light, a subpixel 5210G that emits green light, and a subpixel 5210B that emits blue light. The subpixel 5210R, the subpixel 5210G, and the subpixel 5210B each include a display element and a circuit for controlling the driving of the display element.

A liquid crystal element can be used as the display element, for example. As examples of a liquid crystal element, a transmissive liquid crystal element, a reflective liquid crystal element, and a transflective liquid crystal element can be given.

In addition to a liquid crystal element, various elements (e.g., a light-emitting element) can be used as a display element. Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

### Structure Example 1 of Display Device

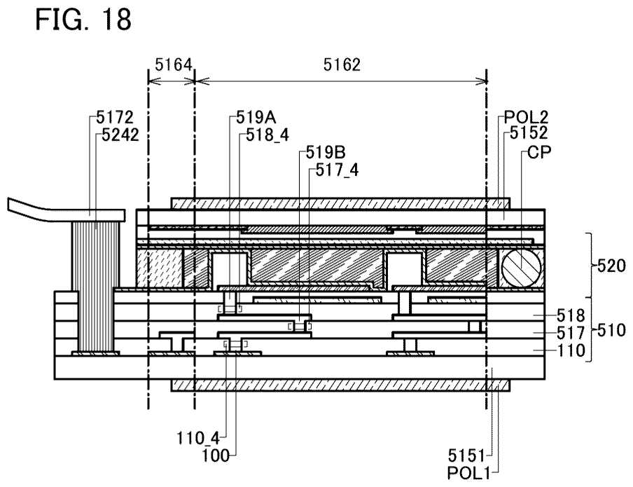

FIG. 18 illustrates an example of cross sections of part of a region including the FPC 5172, part of the circuit portion 5164, part of the display portion 5162, part of the connection portion 5140, and part of a region including the end portion of the display device 5050A.

The display device illustrated in FIG. 18 includes a liquid crystal device that operates in a VA mode.

The substrate 5151 and the substrate 5152 are bonded to each other with an adhesive layer. A liquid crystal is sealed in a region that is surrounded by the substrate 5151, the substrate 5152, and the adhesive layer. A polarizing plate POL2 is provided on an outer surface of the substrate 5152. A polarizing plate POL1 is provided on an outer surface of the substrate 5151.

Although not illustrated, a backlight can be provided outside the polarizing plate POL2 or the polarizing plate POL1.

Note that the transistor included in the circuit portion 5164 and the transistor included in the display portion 5162 may have the same structure or different structures. A plurality of transistors included in the circuit portion 5164 may have the same structure, or transistors with different structures may be used in combination.

A conductive particle CP is electrically connected to a conductive layer provided on the substrate 5151 side in the connection portion 5140. Thus, a potential or a signal can be supplied from the FPC, the IC, or the like placed on the substrate 5151 side.

As the conductive particle CP, a particle of an organic resin, silica, or the like coated with a metal material can be used. It is preferable to use nickel or gold as the metal material because contact resistance can be reduced. It is also preferable to use a particle coated with layers of two or more kinds of metal materials, such as a particle coated with nickel and further with gold. For the conductive particle CP, a material capable of elastic deformation or plastic deformation is preferably used. In that case, the conductive particle CP sometimes has a shape that is vertically crushed. With the crushed shape, the contact area of the conductive particle CP and a conductive layer electrically connected thereto can be increased, whereby contact resistance can be reduced and occurrence of problems such as connection defects can be inhibited.

### Structure Example 2 of Display Device

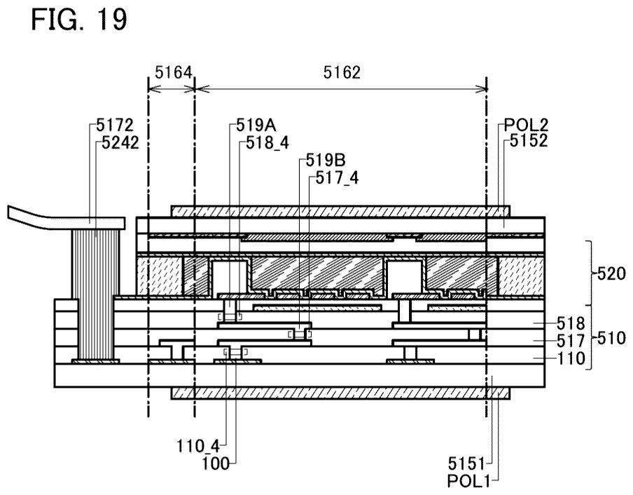

The display device illustrated in FIG. 19 includes a liquid crystal device that operates in an FFS mode. In a plan view, a pixel electrode has a comb-like shape or a shape with a slit. The common electrode is provided to overlap with the pixel electrode.

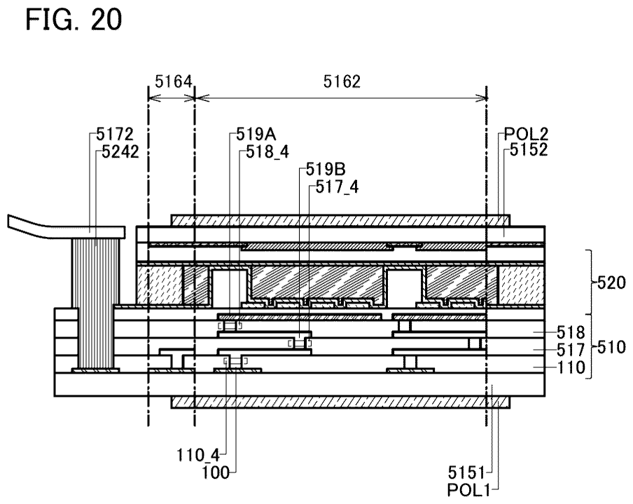

FIG. 20 illustrates an example in which the positions of the pixel electrode and the common electrode are turned upside down. The common electrode has a comb-like shape or includes a slit in a plan view, and is provided over the pixel electrode with the insulating layer therebetween.

### Structure Example 3 of Display Device

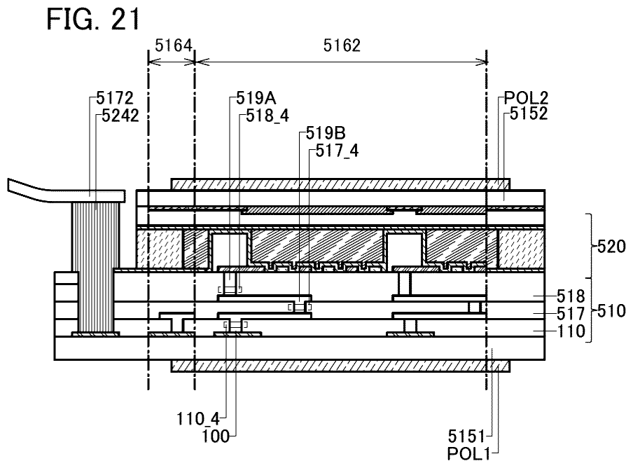

The display device illustrated in FIG. 21 includes a liquid crystal device that operates in an IPS mode.

The pixel electrode and the common electrode are provided over the same insulating layer. In a plan view, the pixel electrode and the common electrode each have a comb-like shape and are provided to engage with each other. The pixel electrode and the common electrode are preferably formed by processing the same conductive film.

At least part of this embodiment can be implemented in combination with any of the other embodiments described in this specification as appropriate.

### Embodiment 3

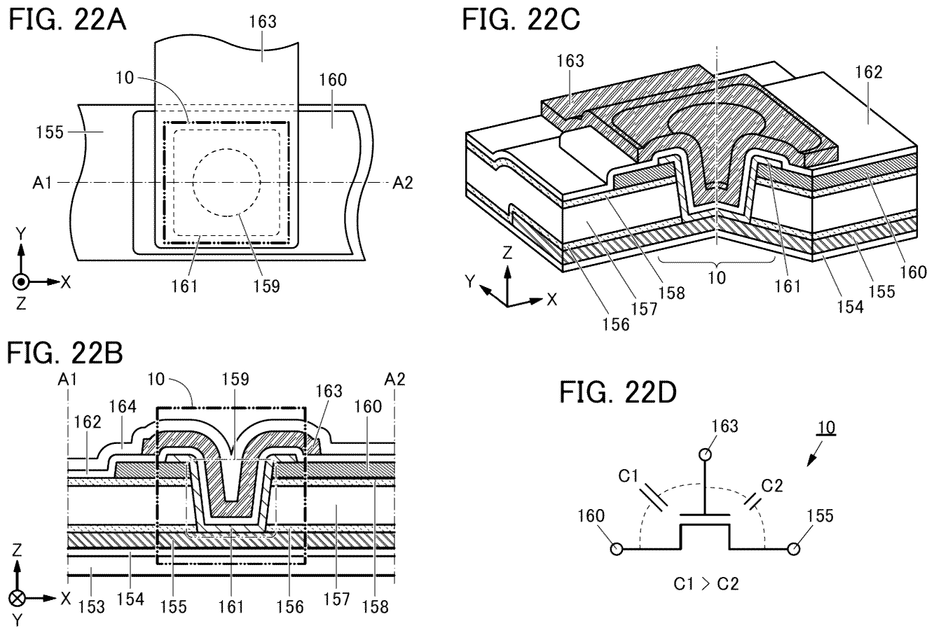

In this embodiment, structures of a transistor that can be used in the semiconductor device of one embodiment of the present invention will be described with reference to FIG. 22 to FIG. 25.

FIG. 22A is a plan view of a transistor 10. FIG. 22B is a cross-sectional view of a portion indicated by the dashed-dotted line A1-A2 in FIG. 22A. FIG. 22C is a perspective view of the transistor 10 part of which is cut out. FIG. 22D is an equivalent circuit diagram of the transistor 10.

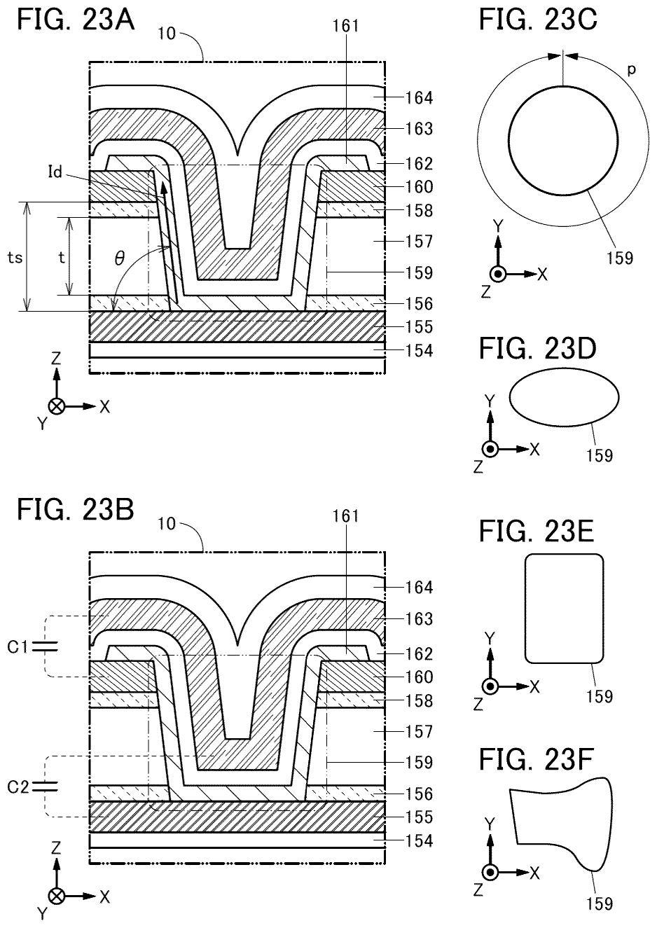

FIG. 23A and FIG. 23B are enlarged views of the transistor 10 illustrated in FIG. 22B. FIG. 23C is a view of an opening 159 seen from the Z direction.

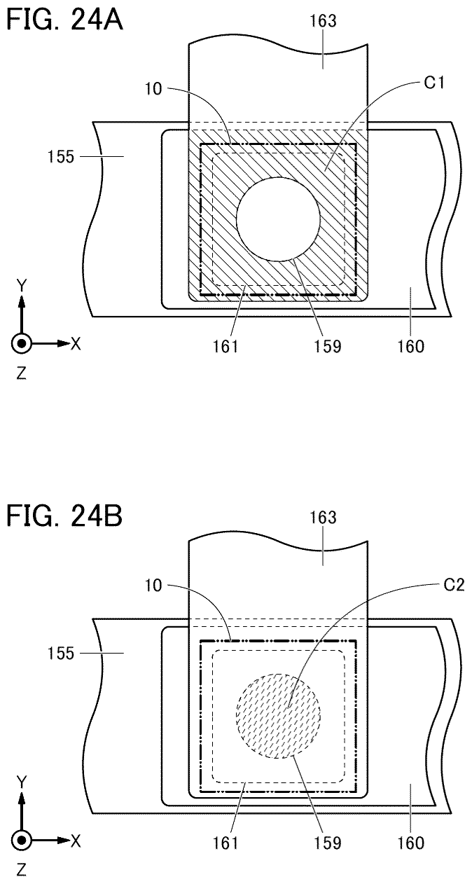

FIG. 24A and FIG. 24B are plan views of the transistor 10.

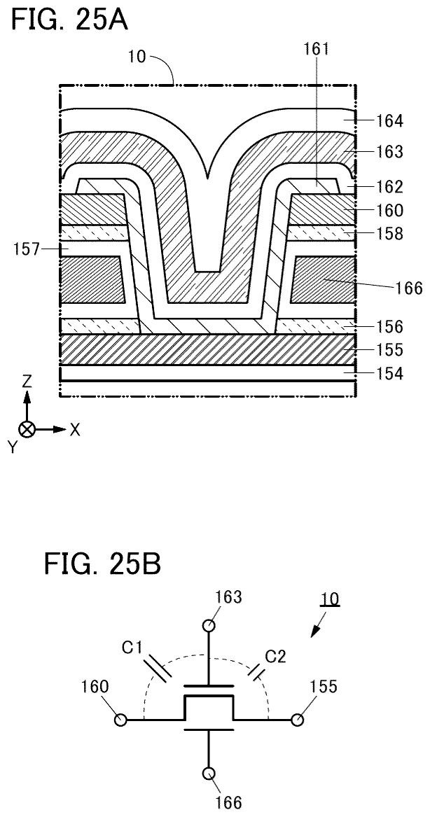

FIG. 25A is a cross-sectional view of the transistor 10, and FIG. 25B is an equivalent circuit diagram of the transistor 10 illustrated in FIG. 25A.

### Structure Example of Transistor

A structure example of the transistor that can be used in the semiconductor device of one embodiment of the present invention will be described in detail. For easy understanding of the structure of the transistor 10, some components of the transistor 10 are not illustrated in FIG. 22A and FIG. 22C. For example, an insulating layer 164 or the like illustrated in FIG. 22B is not illustrated in FIG. 22A and FIG. 22C.

The transistor 10 includes an insulating layer 154 over a substrate 153 and a conductive layer 155 over the insulating layer 154. An insulating layer 156 is provided over the conductive layer 155, an insulating layer 157 is provided over the insulating layer 156, and an insulating layer 158 is provided over the insulating layer 157. A conductive layer 160 is provided over the insulating layer 158.

In a region overlapping with part of the conductive layer 155, the opening 159 is provided in the conductive layer 160, the insulating layer 158, the insulating layer 157, and the insulating layer 156 (see FIG. 22B and FIG. 23A). A semiconductor layer 161 is provided in the opening 159. The semiconductor layer 161 includes a region overlapping with the bottom portion of the opening 159 and a region overlapping with the side surface of the opening 159. The semiconductor layer 161 includes a region in contact with a side surface of the insulating layer 158, a region in contact with a side surface of the insulating layer 157, and a region in contact with a side surface of the insulating layer 156. That is, the part of the semiconductor layer 161 is electrically connected to the conductive layer 160, and the other part of the semiconductor layer 161 is electrically connected to the conductive layer 155.

In the transistor 10, an insulating layer 162 is provided over the insulating layer 158, the conductive layer 160, and the semiconductor layer 161, and a conductive layer 163 is provided over the insulating layer 162. The insulating layer 164 is provided over the insulating layer 162 and the conductive layer 163. The insulating layer 162 includes a region overlapping with the side surface of the opening 159 with the semiconductor layer 161 therebetween. The conductive layer 163 is provided to cover the semiconductor layer 161. Thus, the conductive layer 163 includes a region extending beyond an end portion of the semiconductor layer 161. The conductive layer 163 includes also a region overlapping with the side surface of the opening 159 with the insulating layer 162 and the semiconductor layer 161 therebetween.

The conductive layer 155 includes a region functioning as one of a source electrode and a drain electrode of the transistor 10. The conductive layer 160 includes a region functioning as the other of the source electrode and the drain electrode of the transistor 10. For example, in the case where the conductive layer 155 functions as the drain electrode of the transistor 10, the conductive layer 160 functions as the source electrode of the transistor 10.

The semiconductor layer 161 includes a region functioning as a semiconductor layer of the transistor 10 where a channel is formed; the insulating layer 162 includes a region functioning as a gate insulating layer; and the conductive layer 163 includes a region functioning as a gate electrode. The transistor 10 is provided in a region including the opening 159.

The source electrode and the drain electrode of the transistor 10 are placed in the Z direction. Thus, the source and the drain of the transistor 10 are placed in different positions in the Z direction. For example, with respect to the top surface of the substrate 153, the source and the drain of the transistor 10 are placed at different distances from the top surface of the substrate 153 serving as the reference. Such a transistor is also referred to as a “vertical-channel transistor”, a “vertical transistor”, or a “VFET (Vertical Field Effect Transistor)”. In the vertical-channel transistor, a Z-direction (vertical-direction) component is included in the direction in which drain current I_{d} flows. For example, in the transistor 10 which is a vertical-channel transistor, the angle θ (see FIG. 23A) between the direction in which the drain current I_{d} flows and a surface on which the semiconductor layer 161 over the conductive layer 155 is formed is larger than or equal to 5° and smaller than or equal to 110°, larger than or equal to 10° and smaller than or equal to 90°, larger than or equal to 30° and smaller than or equal to 90°, or larger than or equal to 60° and smaller than or equal to 90° when a cross section passing through the center (or center of gravity) of the opening 159 seen from the Z direction is seen from the X direction or the Y direction.

As described above, the semiconductor layer 161 includes the region in contact with the side surface of the insulating layer 157. Thus, the drain current I_{d} flows along the side surface of the insulating layer 157. Thus, the angle θ between the direction in which the drain current I_{d} flows and the surface on which the semiconductor layer 161 over the conductive layer 155 is formed can be rephrased as the angle θ between the side surface of the insulating layer 157 and the surface on which the semiconductor layer 161 over the conductive layer 155 is formed.

Since the source electrode and the drain electrode of a vertical-channel transistor are placed in the Z direction, the area occupied by the transistor can be reduced. With the use of the vertical-channel transistor for a semiconductor device, the area occupied by the semiconductor device can be significantly reduced.

Here, examples of materials that can be used for the transistor 10 or the semiconductor device of one embodiment of the present invention are described.

### Conductive Layer

As a conductive material used for not only the gate electrode, the source electrode, and the drain electrode of the transistor 10 but also conductive layers such as various wirings and electrodes included in the semiconductor device, a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), and the like; an alloy containing the above metal element as a component; an alloy containing the above metal elements in combination; or the like can be used. Furthermore, a semiconductor typified by polycrystalline silicon containing an impurity element such as phosphorus, or silicide such as nickel silicide may be used. There is no particular limitation on the formation method of the conductive material, and a variety of formation methods such as an evaporation method, an atomic layer deposition (ALD) method, a chemical vapor deposition (CVD) method, a sputtering method, and a spin coating method can be employed.

A Cu—X alloy (X is Mn, Ni, Cr, Fe, Co, Mo, Ta, or Ti) may be used as the conductive material. A layer formed using a Cu—X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive material.

As the conductive material that can be used for the conductive layer, a conductive material containing oxygen, such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added, can be used. A conductive material containing nitrogen, such as titanium nitride, tantalum nitride, or tungsten nitride, can also be used. The conductive layer can have a stacked-layer structure with an appropriate combination of a conductive material containing oxygen, a conductive material containing nitrogen, and a material containing the above-described metal element.

For example, the conductive layer can have a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure of a titanium layer, an aluminum layer stacked over the titanium layer, and a titanium layer further stacked thereover.

Furthermore, a plurality of conductive layers formed with the above conductive materials may be stacked and used. For example, the conductive layer may have a stacked-layer structure in which a material containing the above-described metal element is combined with a conductive material containing oxygen. It is also possible to employ a stacked-layer structure in which a material containing the above-described metal element is combined with a conductive material containing nitrogen. It is also possible to employ a stacked-layer structure in which a material containing the above-described metal element is combined with a conductive material containing oxygen and a conductive material containing nitrogen.

For example, the conductive layer may have a three-layer structure in which a conductive layer containing copper is stacked over a conductive layer containing oxygen and at least one of indium and zinc, and a conductive layer containing oxygen and at least one of indium and zinc is stacked thereover. In that case, a side surface of the conductive layer containing copper is preferably covered with the conductive layer containing oxygen and at least one of indium and zinc. Alternatively, a plurality of conductive layers containing oxygen and at least one of indium and zinc may be stacked and used as the conductive layer, for example.

### Insulating Layer

For each of the insulating layers, a single layer or a stack layer of insulating materials selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like is used. Two or more materials selected from an oxide material, a nitride material, an oxynitride material, and a nitride oxide material may be used.

There is no particular limitation on the formation method of the insulating material, and a variety of formation methods such as an evaporation method, an ALD method, a CVD method, a sputtering method, and a spin coating method can be employed.

Note that in this specification and the like, a nitride oxide refers to a material that contains more nitrogen than oxygen. An oxynitride refers to a material that contains more oxygen than nitrogen. Note that the content of each element can be measured by Rutherford backscattering spectrometry (RBS), for example.

For example, it is preferable that the insulating layer 154 and the insulating layer 164 be formed using an insulating material through which impurities are less likely to pass. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Examples of insulating materials through which impurities are less likely to pass, include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material through which impurities are less likely to pass is used for the insulating layer 154, impurity diffusion from the substrate 153 side can be inhibited, and the reliability of the transistor 10 can be improved. That is, the reliability of a semiconductor device including the transistor 10 can be improved. When the insulating material through which impurities are less likely to pass is used for the insulating layer 164, impurity diffusion from above the insulating layer 164 can be inhibited, and the reliability of the transistor 10 can be improved. That is, the reliability of a semiconductor device including the transistor 10 can be improved.

As the insulating layer, an insulating layer that can function as a planarization layer may be used. Examples of materials of the insulating layer that functions as a planarization layer include an acrylic resin, polyimide, an epoxy resin, polyamide, polyimide amide, a siloxane resin, a benzocyclobutene resin, a phenol resin, and precursors of these resins. Other than the above-described organic materials, it is also possible to use a low-dielectric constant material (a low-k material), a siloxane resin, PSG (phosphosilicate glass), BPSG (borophosphosilicate glass), or the like. Note that a plurality of insulating layers formed of these materials may be stacked.

Note that the siloxane resin corresponds to a resin including a Si—O—Si bond formed using a siloxane-based material as a starting material. The siloxane resin may include an organic group (e.g., an alkyl group or an aryl group) or a fluoro group as a substituent. In addition, the organic group may include a fluoro group.

A surface of the insulating layer or the like may be subjected to CMP treatment. By the CMP treatment, unevenness of a surface of the insulating layer or the like can be reduced, and coverage with an insulating layer and a conductive layer that are formed later can be increased.

### Semiconductor Layer

For the semiconductor layer 161, a single crystal semiconductor, a polycrystalline semiconductor, a microcrystalline semiconductor, an amorphous semiconductor, or the like can be used alone or in combination. As a semiconductor material, a semiconductor material having a band gap (a semiconductor material that is not a zero-gap semiconductor) such as silicon or germanium can be used, for example. For example, a single element semiconductor, a compound semiconductor, or a layered substance (also referred to as an atomic layer substance, a two-dimensional material, or the like) is preferably used as the semiconductor material. As the compound semiconductor, an organic substance having semiconductor characteristics or a metal oxide having semiconductor characteristics (also referred to as an oxide semiconductor) can be used. These semiconductor materials may include an impurity as a dopant.

For example, single crystal silicon, polycrystalline silicon, microcrystalline silicon, or amorphous silicon may be used for the semiconductor layer 161. As the polycrystalline silicon, for example, low-temperature polysilicon (LTPS) may be used.

The transistor including amorphous silicon in the semiconductor layer 161 can be formed over a large glass substrate, and can be manufactured at low cost. The transistor including polycrystalline silicon in the semiconductor layer 161 has high field-effect mobility and enables high-speed operation. The transistor including microcrystalline silicon in the semiconductor layer 161 has higher field-effect mobility and enables higher speed operation than the transistor including amorphous silicon.

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

The semiconductor layer 161 may include a layered substance functioning as a semiconductor. The layered substance is a general term of a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the layered substance include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the above-described transition metal chalcogenide for the semiconductor layer enables a memory device with a high on-state current to be provided.

An oxide semiconductor has a band gap of 2 eV or more; thus, a transistor using an oxide semiconductor, which is a kind of metal oxide, for a semiconductor layer where a channel is formed (also referred to as an “OS transistor”) has an extremely low off-state current. Thus, the power consumption of a semiconductor device including an OS transistor can be reduced. The OS transistor operates stably even in a high-temperature environment and has small change in characteristics. For example, the off-state current hardly increases even in a high-temperature environment. Specifically, the off-state current hardly increases even at an environmental temperature higher than or equal to room temperature and lower than or equal to 200 °C. Furthermore, the on-state current of the OS transistor is unlikely to decrease even in a high-temperature environment. Therefore, the semiconductor device including the OS transistor can operate stably and have high reliability even in a high-temperature environment.

Note that in this embodiment and the like, an OS transistor is preferably used as the transistor 10. Since an OS transistor has a high breakdown voltage between the source and the drain, the channel length can be shortened. The on-state current can be increased accordingly. The OS transistor is suitably used as a vertical-channel transistor.

A channel length L can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L can be greater than or equal to 100 nm and less than or equal to 1 μm.

Examples of the metal oxide that can be used for the semiconductor layer of the OS transistor include indium oxide, gallium oxide, and zinc oxide. The metal oxide preferably contains at least indium (In) or zinc (Zn). The metal oxide preferably contains two or three kinds selected from indium, an element M, and zinc. The element M is a metal element or metalloid element that has a high bonding energy with oxygen, such as a metal element or metalloid element whose bonding energy with oxygen is higher than that of indium, for example.

Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more of the above elements, further preferably one or more selected from aluminum, gallium, tin, and yttrium, still further preferably gallium. In this specification and the like, a metal element and a metalloid element may be collectively referred to as a “metal element”, and a “metal element” in this specification and the like may refer to a metalloid element.

For example, it is possible to use indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like. Alternatively, it is possible to use indium tin oxide containing silicon, gallium tin oxide (Ga—Sn oxide), aluminum tin oxide (Al—Sn oxide), or the like.

By increasing the proportion of the number of indium atoms in the total number of atoms of all the metal elements contained in the metal oxide, the field-effect mobility of the transistor can be increased.

Note that the metal oxide may contain, instead of indium or in addition to indium, one or more metal elements with large period numbers. The larger the overlap between orbits of metal elements is, the more likely it is that the metal oxide will have high carrier conductivity. Thus, a transistor including a metal element with a large period number can have high field-effect mobility in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of metal elements in the main constituent elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of atoms of the element M in the total number of atoms of metal elements in the main constituent elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is inhibited, and the reliability of the transistor can be increased.

Electrical characteristics and reliability of a transistor depend on the composition of the metal oxide used for the semiconductor layer. Therefore, by changing the composition of the metal oxide in accordance with the electrical characteristics and reliability required for the transistor, the semiconductor device can have both excellent electrical characteristics and high reliability.

In the case of using In—Zn oxide for the semiconductor layer of the OS transistor, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof.

In the case of using In—Sn oxide for the semiconductor layer of the OS transistor, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, In:Sn=10:1, or the neighborhood thereof.

In the case of using In—Sn—Zn oxide for the semiconductor layer of the OS transistor, a metal oxide in which the atomic proportion of indium is higher than the atomic proportion of tin can be used. It is further preferable to use a metal oxide in which the atomic ratio of zinc is higher than the atomic ratio of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case of using In—Al—Zn oxide for the semiconductor layer of the OS transistor, a metal oxide in which the atomic proportion of indium is higher than the atomic proportion of aluminum can be used. It is further preferable to use a metal oxide in which the atomic ratio of zinc is higher than the atomic ratio of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case of using In—Ga—Zn oxide for the semiconductor layer of the OS transistor, a metal oxide in which the proportion of the number of indium atoms in the number of atoms of the metal elements is higher than the proportion of the number of gallium atoms can be used. It is further preferable to use a metal oxide in which the proportion of the number of zinc atoms is higher than the proportion of the number of gallium atoms. For example, it is possible to use a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or the neighborhood thereof.

In the case of using In-M-Zn oxide for the semiconductor layer of the OS transistor, a metal oxide in which the proportion of the number of indium atoms in the number of atoms of the metal elements is higher than the proportion of the number of element M atoms can be used. It is further preferable to use a metal oxide in which the atomic ratio of zinc is higher than the atomic ratio of the element M. For example, it is possible to use a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the neighborhood thereof.

In the case where a plurality of metal elements are contained as the element M, the sum of the atomic ratios of the metal elements can be the atomic ratio of the element M. In the case of In—Ga—Al—Zn oxide in which gallium and aluminum are contained as the element M, for example, the sum of the atomic ratio of gallium and the atomic ratio of aluminum can be the atomic ratio of the element M. The atomic ratio of indium to the element M to zinc is preferably within the ranges given above.

It is preferable to use a metal oxide in which the proportion of the number of indium atoms in the total number of atoms of metal elements in the main elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case where In-M-Zn oxide is used for the semiconductor layer, the proportion of the number of indium atoms in the total number of atoms of indium, the element M, and zinc is preferably within the ranges given above.

As described above, by increasing the proportion of the number of indium atoms in the total number of atoms of metal elements in the main elements contained in the metal oxide, the field-effect mobility of the transistor can be increased. With the use of such a transistor, a circuit capable of high-speed operation can be formed. Furthermore, the area occupied by the circuit can be reduced. The application of the transistor to a large-sized display device or a high-definition display device can reduce signal delay in wirings and reduce display unevenness even if the number of wirings is increased, for example. In addition, since the area occupied by the circuit can be reduced, the bezel of the display device can be narrowed.

For analysis of the composition of a metal oxide, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an ALD method is suitable for forming the metal oxide. Note that in the case where the metal oxide is formed by a sputtering method, the atomic ratio of a target may be different from the atomic ratio of the metal oxide. In particular, the atomic proportion of zinc in the metal oxide is lower than the atomic proportion of zinc in the target in some cases. Specifically, the atomic proportion of zinc contained in the metal oxide may be approximately 40% to 90% of the atomic proportion of zinc contained in the target.

With use of a metal oxide that does not contain gallium or has a low gallium content percentage in the semiconductor layer, the transistor can be highly reliable against positive bias application. That is, the amount of change in the threshold voltage of the transistor in the PBTS test can be small. Meanwhile, with use of a metal oxide that contains gallium, the gallium content percentage is preferably lower than the indium content percentage. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, at the interface between a metal oxide containing a large amount of gallium and the gate insulating layer, gallium is bonded to excess oxygen in the gate insulating layer, which probably generates trap sites of carriers (here, electrons) easily. This might cause the change in the threshold voltage when a positive potential is supplied to a gate and carriers are trapped at the interface between the semiconductor layer and the gate insulating layer.

More specifically, in the case where In—Ga—Zn oxide is used for the semiconductor layer, a metal oxide in which the atomic ratio of indium is higher than the atomic ratio of gallium can be used for the semiconductor layer. It is further preferable to use a metal oxide in which the atomic ratio of zinc is higher than the atomic ratio of gallium. In other words, a metal oxide in which the atomic ratio of metal elements satisfies In>Ga and Zn>Ga is preferably used for the semiconductor layer.

For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof may be used for the semiconductor layer of the OS transistor.

The semiconductor layer of the OS transistor is preferably formed using a metal oxide having the following compositions: the proportion of the number of gallium atoms in the number of atoms of the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the proportion of the number of gallium atoms in the number of atoms of the metal elements in the semiconductor layer enables the transistor to be highly resistant to the PBTS test. Note that oxygen vacancy (V_{O}) is less likely to be generated in the metal oxide when the metal oxide contains gallium.

A metal oxide not containing gallium may be used for the semiconductor layer of the OS transistor. For example, In—Zn oxide can be used for the semiconductor layer. In this case, when the ratio of the number of indium atoms in the number of atoms of the metal elements contained in the metal oxide is increased, the field-effect mobility of the transistor can be increased. By contrast, when the ratio of the number of zinc atoms in the number of atoms of the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer. The use of a metal oxide not containing gallium can make a change in the threshold voltage particularly in the PBTS test extremely small.

For example, an oxide containing indium and zinc can be used for the semiconductor layer. In that case, for example, a metal oxide where the atomic ratio of metal elements is In:Zn=2:3, In:Zn=4:1, or the neighborhood thereof can be used.

Although the case of using gallium is described as a typical example, the same applies to the case where the element M is used instead of gallium. A metal oxide in which the atomic ratio of indium is higher than the atomic ratio of the element M is preferably used for the semiconductor layer. Furthermore, a metal oxide in which the atomic ratio of zinc is higher than the atomic ratio of the element M is preferably used.

The use of a metal oxide having a low content percentage of the element M for the semiconductor layer achieves the transistor that is highly reliable against positive bias application. With use of the transistor as a transistor that is required to have high reliability against positive bias application, a highly reliable semiconductor device can be achieved.

Next, the reliability of a transistor against light is described.

Light incidence on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in an NBTIS test, for example.

The high content percentage of the element M in the metal oxide used for the semiconductor layer enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide in the semiconductor layer is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, it is possible to use, for the semiconductor layer, a metal oxide in which the atomic ratio of the metal elements is In:M:Zn=1:1:1, In:M:Zn=1:1:1.2, In:M:Zn=1:3:2, In:M:Zn=1:3:3, In:M:Zn=1:3:4, or the neighborhood thereof.

For the semiconductor layer, it is particularly preferable to use a metal oxide in which the proportion of the number of element M atoms in the number of atoms of the metal elements contained is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet further preferably higher than or equal to 50 atomic % and lower than or equal to 60 atomic %.

In the case where In—Ga—Zn oxide is used for the semiconductor layer, a metal oxide in which the proportion of the number of indium atoms in the number of atoms of the metal elements is lower than or equal to the proportion of the number of gallium atoms can be used. For example, it is possible to use a metal oxide in which the atomic ratio of the metal elements is In:Ga:Zn=1:1:1, In:Ga:Zn=1:1:1.2, In:Ga:Zn=1:3:2, In:Ga:Zn=1:3:3, In:Ga:Zn=1:3:4, or the neighborhood thereof.

For the semiconductor layer, it is particularly preferable to use a metal oxide in which the proportion of the number of gallium atoms in the number of atoms of the metal elements contained is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, still further preferably higher than or equal to 40 atomic % and lower than or equal to 60 atomic %, yet further preferably higher than or equal to 50 atomic % and lower than or equal to 60 atomic %.

The use of a metal oxide having a high content percentage of the element M for the semiconductor layer enables the transistor to be highly reliable against light. The use of the transistor as a transistor that is required to have high reliability against light enables a semiconductor device to have high reliability.

The semiconductor layer may have a stacked-layer structure including two or more metal oxide layers. The two or more metal oxide layers included in the semiconductor layer may have the same composition or substantially the same compositions.. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a two-layer stacked structure of a first metal oxide layer having a composition of In:M:Zn=1:3:4 [atomic ratio] or a composition in the neighborhood thereof and a second metal oxide layer having a composition of In:M:Zn=1:1:1 [atomic ratio] or a composition in the neighborhood thereof and overlapping with the first metal oxide layer may be employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

For example, a stacked-layer structure of a first metal oxide layer having a composition of In:M:Zn=1:1:1 [atomic ratio] or a composition in the neighborhood thereof and a second metal oxide layer having a composition of In:Zn=4:1 [atomic ratio] or a composition in the neighborhood thereof and being provided over the first metal oxide layer may be used.

For example, a three-layer stacked structure in which a semiconductor layer having an atomic ratio of metal elements of In:Ga:Zn=1:1:1 is the first layer, a semiconductor layer having an atomic ratio of metal elements of In:Zn=4:1 is the second layer, and a semiconductor layer having an atomic ratio of metal elements of In:Ga:Zn=1:1:1 is the third layer may be employed. Note that the band gaps of the first and third semiconductor layers are preferably larger than the band gap of the second semiconductor layer. With this structure, the main current path can be the second-layer semiconductor layer, so that what is called a buried channel structure can be obtained.

It is preferable to use a metal oxide layer having crystallinity as the semiconductor layer. For example, a metal oxide layer having a CAAC (c-axis aligned crystal) structure, a polycrystalline (poly-crystal) structure, a nano-crystal (nc) structure, or the like can be used. With use of a metal oxide layer having crystallinity as the semiconductor layer, the density of defect states in the semiconductor layer can be reduced, which achieves a highly reliable display device. Note that the CAAC structure is a crystal structure in which a plurality of microcrystals (typically, a plurality of IGZO microcrystals) have c-axis alignment and the plurality of microcrystals are connected in an a-b plane without alignment. The CAAC structure has a smaller amount of crystal grain boundary, grain, or the like in the a-b plane than a poly crystalline structure, and thus can achieve a highly reliable display device.

The higher the crystallinity of the metal oxide layer used as the semiconductor layer is, the lower the density of defect states in the semiconductor layer can be. By contrast, the use of a metal oxide layer having low crystallinity achieves a transistor through which a large amount of current can flow.

In the case where the metal oxide layer is formed by a sputtering method, the higher the substrate temperature (the stage temperature) in the formation is, the higher the crystallinity of the formed metal oxide layer can be. The metal oxide layer with higher crystallinity can be formed as the proportion of a flow rate of an oxygen gas to the whole film formation gas (also referred to as oxygen flow rate ratio) used in film formation is increased.

The semiconductor layer of the OS transistor may have a stacked-layer structure of two or more metal oxide layers having different crystallinities. For example, a stacked-layer structure of the first metal oxide layer and the second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer may have different compositions.

The channel length L of the transistor 10 described in this embodiment is determined by the thickness of the insulating layer provided between the conductive layer 160 and the conductive layer 155. As a result, the transistor with a short channel length L can be formed with high accuracy. In addition, variations in characteristics among a plurality of transistors 10 are also reduced. Thus, the semiconductor device including the transistors 10 can operate stably and have high reliability. When the variations in characteristics are reduced, the circuit design flexibility of the semiconductor device is increased and the operation voltage can be reduced. Thus, the power consumption of the semiconductor device can be reduced.

In the case where an oxide semiconductor is used for the semiconductor layer 161, a material containing hydrogen is preferably used for the insulating layer 156 and the insulating layer 158. When the insulating layer containing hydrogen is in contact with the oxide semiconductor, the oxide semiconductor in a region in contact with the insulating layer becomes an n-type semiconductor and can function as a source region or a drain region. For example, a material containing silicon, nitrogen, and hydrogen may be used for the insulating layer. Specifically, silicon nitride containing hydrogen or silicon nitride oxide containing hydrogen may be used.

In the case where an oxide semiconductor is used for the semiconductor layer 161, a conductive material that makes the oxide semiconductor an n-type semiconductor is preferably used for the conductive layer 155 in contact with the semiconductor layer 161 and the conductive layer 160 in contact with the semiconductor layer 161. For example, a conductive material containing nitrogen may be used. For example, a conductive material containing nitrogen and titanium or tantalum may be used. Another conductive material may be provided so as to overlap with the conductive material containing nitrogen.

Meanwhile, for the insulating layer 157, a material which contains oxygen and a reduced amount of hydrogen is preferably used. For example, a material containing silicon and oxygen may be used. Specifically, silicon oxide, silicon oxynitride, or the like may be used. Since hydrogen is an impurity element in an oxide semiconductor, when the semiconductor layer 161, which is an oxide semiconductor, and the insulating layer 157, which contains a reduced amount of hydrogen, are in contact with each other, the semiconductor layer 161 is less likely to become an n-type layer. Furthermore, when the semiconductor layer 161, which is an oxide semiconductor, and the insulating layer 157 containing oxygen are in contact with each other, oxygen vacancies in the semiconductor layer 161 are reduced and the transistor 10 has stable characteristics and improved reliability.

When an oxide semiconductor is used for the semiconductor layer 161, the insulating layer 157 preferably contains excess oxygen. In this specification and the like, “excess oxygen” refers to oxygen that is released by heating. In the case where a material containing excess oxygen is used for the insulating layer 157, a material through which oxygen is less likely to pass is preferably used for the insulating layer 156 and the insulating layer 158. Examples of the material through which oxygen is less likely to pass include a nitride of silicon and an oxide containing one or both of aluminum and hafnium. When the material through which oxygen is less likely to pass is used for the insulating layer 156 and the insulating layer 158, excess oxygen contained in the insulating layer 157 is less likely to be released to a lower layer or an upper layer. Thus, a sufficient amount of oxygen can be supplied to the oxide semiconductor. For example, an insulating layer containing silicon and oxygen (the insulating layer 157) can be provided between two insulating layers containing silicon and nitrogen (the insulating layer 156 and the insulating layer 158).

In the case where an oxide semiconductor is used for the semiconductor layer 161 and a material containing hydrogen is used for the insulating layer 156 and the insulating layer 158, a region of the semiconductor layer 161 in contact with the conductive layer 160 and a region of the semiconductor layer 161 in contact with the insulating layer 158 serve as one of a source (a source region) and a drain (a drain region). A region of the semiconductor layer 161 in contact with the conductive layer 155 and a region of the semiconductor layer 161 in contact with the insulating layer 156 serve as the other of the source (the source region) and the drain (the drain region). Thus, a thickness t of the insulating layer 157 determines the channel length L of the transistor 10 (see FIG. 23A).

A material that contains no hydrogen or an extremely small amount of hydrogen may be used for the insulating layer 156 and the insulating layer 158. For example, silicon nitride that contains an extremely small amount of hydrogen or silicon nitride oxide that contains an extremely small amount of hydrogen may be used. In that case, the region of the semiconductor layer 161 that is in contact with the insulating layer 156 and the region of the semiconductor layer 161 that is in contact with the insulating layer 158 do not become n-type regions. Thus, the region of the semiconductor layer 161 in contact with the conductive layer 160 serves as one of a source (a source region) and a drain (a drain region). The region of the semiconductor layer 161 in contact with the conductive layer 155 serves as the other of the source (the source region) and the drain (the drain region). In that case, a thickness ts obtained by combining the thicknesses of the insulating layer 156, the insulating layer 157, and the insulating layer 158 corresponds to the channel length L of the transistor 10 (see FIG. 23A).

The channel length L can be controlled by adjusting the thicknesses of the insulating layer 156, the insulating layer 157, and the insulating layer 158. The channel length L can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L can be greater than or equal to 100 nm and less than or equal to 1 μm.

Although an example in which three insulating layers (the insulating layer 156, the insulating layer 157, and the insulating layer 158) are provided between the conductive layer 155 and the conductive layer 160 is shown in this embodiment, the number of insulating layers between the conductive layer 155 and the conductive layer 160 is not limited thereto. The number of insulating layers between the conductive layer 155 and the conductive layer 160 can be one or two. In addition, the number of layers can be four or more.

Since the semiconductor layer 161 is provided in the opening 159, a length p of the perimeter of the opening 159 corresponds to a channel width W of the transistor 10 (see FIG. 23C). The length p of the perimeter is obtained at a position corresponding to the half (t/2) of the thickness t of the insulating layer 157 or the half (ts/2) of the thickness ts, for example. Note that the length of the circumference of the opening 159 at an arbitrary position may be regarded as the channel width W as necessary. For example, the length p of the perimeter at the lowermost portion of the opening 159 may be regarded as the channel width W, or the length p of the perimeter at the uppermost portion of the opening 159 may be regarded as the channel width W.

The outline (the planar shape) of the opening 159 seen from the Z direction is illustrated as being circular in FIG. 23C but is not limited to this. For example, the outline of the opening 159 seen from the Z direction can be an elliptical shape (see FIG. 23D). The outline also can be rectangle shape (see FIG. 23E). Note that FIG. 23E illustrates a rectangle having rounded corner portions. For example, the outline of the opening 159 seen from the Z direction may have a shape including a straight portion and/or a curved portion (see FIG. 23F).

In the transistor 10 of one embodiment of the present invention, the capacitance value of parasitic capacitance generated between the gate and the source and the capacitance value of parasitic capacitance generated between the gate and the drain are different from each other. Specifically, the capacitance value of a capacitor C1 generated in a region where the conductive layer 160 and the conductive layer 163 overlap with each other over the insulating layer 154 is larger than the capacitance value of a capacitor C2 generated in a region where the conductive layer 155 and the conductive layer 163 overlap with each other in the opening 159 (see FIG. 22D and FIG. 23B).

When the transistor 10 of one embodiment of the present invention is seen from the Z direction, the conductive layer 163 overlaps with the conductive layer 160 in the periphery of the opening 159 to surround the opening 159, and overlaps with the conductive layer 155 in the bottom portion of the opening 159 (see FIG. 24A and FIG. 24B).

In FIG. 24A, a region functioning as the capacitor C1 when seen from the Z direction is shown with a hatching pattern. A region where the conductive layer 160 and the conductive layer 163 overlap with each other with the semiconductor layer 161 and the insulating layer 162 interposed therebetween over the insulating layer 154 functions as the capacitor C1 (see FIG. 23B and FIG. 24A). Note that the insulating layer 154 and the insulating layer 162 are not illustrated in FIG. 24A.

In FIG. 24B, a region functioning as the capacitor C2 when seen from the Z direction is shown with a hatching pattern. In the bottom portion of the opening 159, a region where the conductive layer 155 and the conductive layer 163 overlap with each other with the semiconductor layer 161 and the insulating layer 162 interposed therebetween functions as the capacitor C2 (see FIG. 23B and FIG. 24B). Note that the insulating layer 154 and the insulating layer 162 are not illustrated in FIG. 24B.

According to FIG. 24A and FIG. 24B, the region functioning as the capacitor C1 has a larger area than the region functioning as the capacitor C2. When the area of the region functioning as the capacitor C1 is larger than the area of the region functioning as the capacitor C2, the capacitance value of the capacitor C1 is larger than that of the capacitor C2.

When the area where the conductive layer 155 and the conductive layer 163 overlap with each other is changed in order to change the capacitance value of the capacitor C2, the shape of the opening 159 is changed; that is, the length p of the perimeter of the opening 159 is changed. Since the change in the length p of the perimeter directly influences the electrical characteristics of the transistor 10, the capacitance value of the capacitor C2 is difficult to control.

In contrast, the area where the conductive layer 163 and the conductive layer 160 overlap with each other is easy to control and less likely to influence the electrical characteristics of the transistor 10. For example, by increasing the area where the conductive layer 163 and the conductive layer 160 overlap with each other, the capacitance value of the capacitor C1 can be increased.

As illustrated in a cross-sectional view in FIG. 25A, a conductive layer 166 which is close to the semiconductor layer 161 may be provided in the insulating layer 157. The conductive layer 166 is provided not to be in contact with the semiconductor layer 161. The conductive layer 166 is preferably provided to surround the semiconductor layer 161. The conductive layer 166 can function as a back gate electrode of the transistor 10 when provided close to the semiconductor layer 161 without being in contact with the semiconductor layer 161. Thus, the transistor 10 illustrated in FIG. 25A functions as a transistor having a back gate (a back gate electrode). Note that FIG. 25B is an equivalent circuit diagram of the transistor 10 illustrated in FIG. 25A.

Here, a back gate electrode is described. In general, a back gate electrode is formed using a conductive layer and positioned so that a channel formation region in a semiconductor layer can be sandwiched between the gate electrode and the back gate electrode. Thus, the back gate electrode can function in a manner similar to that of the gate electrode. The potential of the back gate electrode may be equal to the potential of the gate electrode or may be a GND potential or a given potential. When the gate electrode and the back gate electrode are electrically connected to each other, the on-state current of the transistor can be increased. When the potential of the back gate electrode is not equal to and is changed independently of the potential of the gate electrode, the threshold voltage of the transistor can be changed.

In addition, the gate electrode and the back gate electrode are formed using conductive layers and thus each have a function of preventing an electric field generated outside the transistor from affecting the channel formation region in the semiconductor layer (in particular, an electric field blocking function against static electricity and the like). As a result, variations in characteristics among transistors are reduced. Furthermore, degradation of transistor characteristics due to the GBTS test is inhibited. For example, with the back gate electrode, a change in threshold voltage in the GBTS test can be inhibited. The transistor including the back gate electrode has a smaller amount of change in threshold voltage in the GBTS test than a transistor including no back gate electrode.

Note that the GBTS (NBTS and PBTS) test is a kind of accelerated test and can evaluate, in a short time, a change by long-term use (i.e., a change over time) in characteristics of a transistor. In particular, the amount of change in the threshold voltage of the transistor in the GBTS test is an important indicator for examination of the reliability. The smaller the amount of change in the threshold voltage in the GBTS test is, the higher the reliability of the transistor becomes.

In the case where light enters from the back gate electrode side, when the back gate electrode is formed using a light-blocking conductive film, light can be prevented from entering the semiconductor layer from the back gate electrode side. Similarly, when the gate electrode is formed using a light-blocking conductive film, light can be prevented from entering the semiconductor layer from the gate electrode side. When one or both of the gate electrode and the back gate electrode is/are formed using a light-blocking conductive film, photodegradation of the semiconductor layer can be prevented and degradation in electrical characteristics of the transistor, such as a shift of the threshold voltage, can be prevented.

In addition, the gate electrode and the back gate electrode can block an electric field generated from the drain electrode so that the electric field do not influence the semiconductor layer. Thus, a change in the current onset voltage due to a change in drain voltage can be inhibited. Note that this effect is significant when a potential is supplied to each of the gate electrode and the back gate electrode.

When a plurality of transistors 10 are connected in parallel, an apparent channel width W of the transistor 10 can be increased. A larger channel width W of the transistor 10 leads to a smaller resistance value between the source and the drain in an on state and thus the drain current I_{d} in the on state can be increased.

### Substrate

There is no particular limitation on a material used for the substrate. The material can be determined in accordance with the purpose in consideration of whether it has a light-transmitting property, heat resistance high enough to withstand heat treatment, or the like. For example, an insulating substrate such as a glass substrate of barium borosilicate glass, aluminoborosilicate glass, or the like, a ceramic substrate, a quartz substrate, or a sapphire substrate can be used. Alternatively, a semiconductor substrate, a flexible substrate, a laminate film, a base film, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. The semiconductor substrate may be a single crystal semiconductor or polycrystalline semiconductor substrate.

When the transistor 10 or the like of one embodiment of the present invention is used for a display device, a large-sized glass substrate of the 6th generation (1500 mm×1850 mm), the 7th generation (1870 mm×2200 mm), the 8th generation (2200 mm×2400 mm), the 9th generation (2400 mm×2800 mm), or the 10th generation (2950 mm×3400 mm), for example, can be used. Thus, a large-sized display device can be manufactured. With the increase in substrate size, a larger number of display devices can be produced from one substrate, which can reduce production cost.

As the materials of the flexible substrate, the laminate film, the base film, and the like, for example, a polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, polyamide imide, polyurethane, polyvinyl chloride, polyvinylidene chloride, polypropylene, polytetrafluoroethylene (PTFE), an ABS resin, cellulose nanofiber, or the like can be used.

When the above-described material is used for the substrate, a lightweight semiconductor device including the transistor 10 can be provided. Furthermore, when the above-described material is used for the substrate, a shock-resistant semiconductor device can be provided. Moreover, when the above-described material is used for the substrate, a semiconductor device that is less likely to be broken can be provided.

The flexible substrate used as the substrate preferably has a lower coefficient of linear expansion because deformation due to an environment is inhibited. For the flexible substrate used as the substrate, for example, a material whose coefficient of linear expansion is lower than or equal to 1×10−−3/K, lower than or equal to 5×10−−5/K, or lower than or equal to 1×10⁻⁵/K is used. In particular, aramid is suitable for the flexible substrate because of its low coefficient of linear expansion.

Note that this embodiment can be combined with any of the other embodiments in this specification as appropriate.

### Embodiment 4

In this embodiment, a display device of one embodiment of the present invention is described. The semiconductor device of one embodiment of the present invention can be used for a display device.

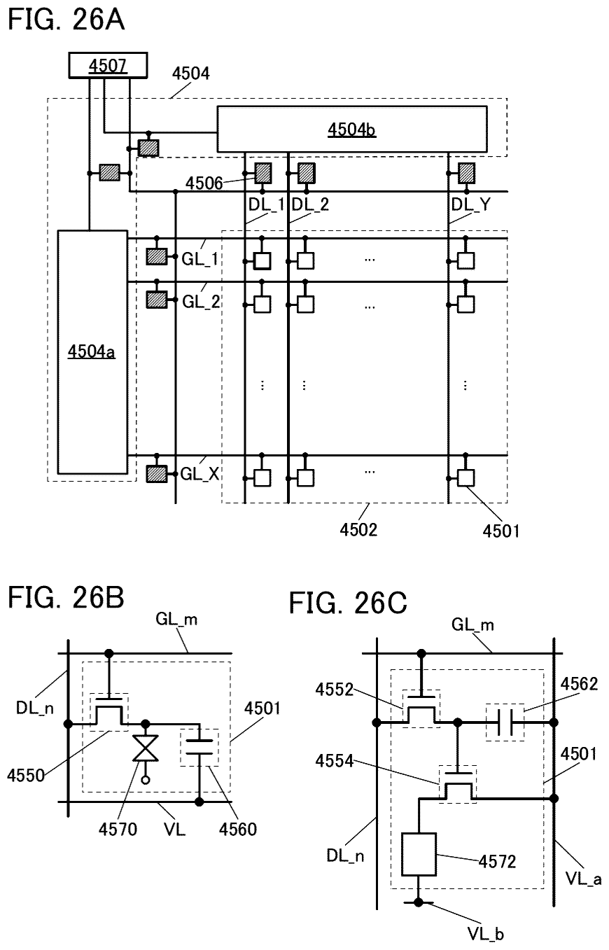

A display device illustrated in FIG. 26A includes a pixel portion 4502, a driver circuit portion 4504, protection circuits 4506, and a terminal portion 4507. Note that a structure in which the protection circuits 4506 are not provided may be employed.

The pixel portion 4502 includes a plurality of pixel circuits 4501 arranged in X rows and Y columns (X and Y each independently represent a natural number of 2 or more). Each of the pixel circuits 4501 includes a circuit for driving a display element.

The driver circuit portion 4504 includes driver circuits such as a gate driver 4504a that outputs a scan signal to a gate line GL_1 to a gate line GL_X and a source driver 4504b that supplies a data signal to a data line DL_1 to a data line DL_Y. The gate driver 4504a can include at least a shift register. The source driver 4504b can be formed using a shift register, a digital-analog convertor circuit, a latch circuit, and the like.

The terminal portion 4507 is a portion provided with terminals for inputting power, control signals, image signals, and the like to the display device from external circuits.

The protection circuits 4506 are each a circuit that, when a potential out of a certain range is supplied to a wiring to which the protection circuit 4506 is connected, establishes continuity between the wiring and another wiring. The protection circuits 4506 illustrated in FIG. 26A are connected to, for example, wirings such as a gate line and a data line. Note that the protection circuits 4506 are shown with a hatching pattern in FIG. 26A to distinguish the protection circuits 4506 from the pixel circuits 4501.

The gate driver 4504a and the source driver 4504b may be provided over the same substrate as the pixel portion 4502, or an IC on which a gate driver circuit or a source driver circuit is formed may be mounted on a substrate provided with the pixel portion 4502 by a chip on glass (COG) method or the like. Alternatively, a flexible printed circuit (FPC) on which an IC is mounted may be attached to a substrate with an anisotropic conductive film (ACF) or the like.

In particular, the pixel portion 4502 and the gate driver 4504a are preferably formed over the same substrate through the same manufacturing step. In that case, the transistor of one embodiment of the present invention is preferably provided in each of the pixel portion 4502 and the gate driver 4504a. In the case where an IC is used for the source driver 4504b, a demultiplexer circuit is preferably provided over the substrate, in which case the number of IC terminals can be reduced. In that case, the transistor of one embodiment of the present invention is preferably provided in the demultiplexer circuit.

FIG. 26B illustrates a configuration example of a pixel circuit applicable to the pixel circuits 4501.

The pixel circuit 4501 illustrated in FIG. 26B includes a liquid crystal device 4570, a transistor 4550, and a capacitor element 4560. The data line DL_n, the gate line GL_m, a potential supply line, and the like are connected to the pixel circuit 4501.

As the transistor 4550, the vertical transistor of one embodiment of the present invention can be used.

The potential of one of a pair of electrodes of the liquid crystal device 4570 is set as appropriate in accordance with the specifications of the pixel circuit 4501. The alignment state of the liquid crystal device 4570 is set depending on written data. Note that a common potential may be supplied to one of the pair of electrodes of the liquid crystal device 4570 included in each of the plurality of pixel circuits 4501. Alternatively, a potential supplied to one of the pair of electrodes of the liquid crystal device 4570 of the pixel circuit 4501 may differ between rows.

The pixel circuit 4501 illustrated in FIG. 26C includes a transistor 4552, a transistor 4554, a capacitor element 4562, and a light-emitting element 4572. The data line DL_n, the gate line GL_m, a potential supply line VL_a, a potential supply line VL_b, and the like are connected to the pixel circuit 4501.

Note that a high power supply potential VDD is supplied to one of the potential supply line VL_a and the potential supply line VL_b, and a low power supply potential VSS is supplied to the other. Current flowing through the light-emitting element 4572 is controlled in accordance with a potential supplied to a gate of the transistor 4554, whereby the luminance of light emitted from the light-emitting element 4572 is controlled.

Next, a pixel circuit including a memory for correcting gray levels displayed by pixels and a display device including the pixel circuit will be described.

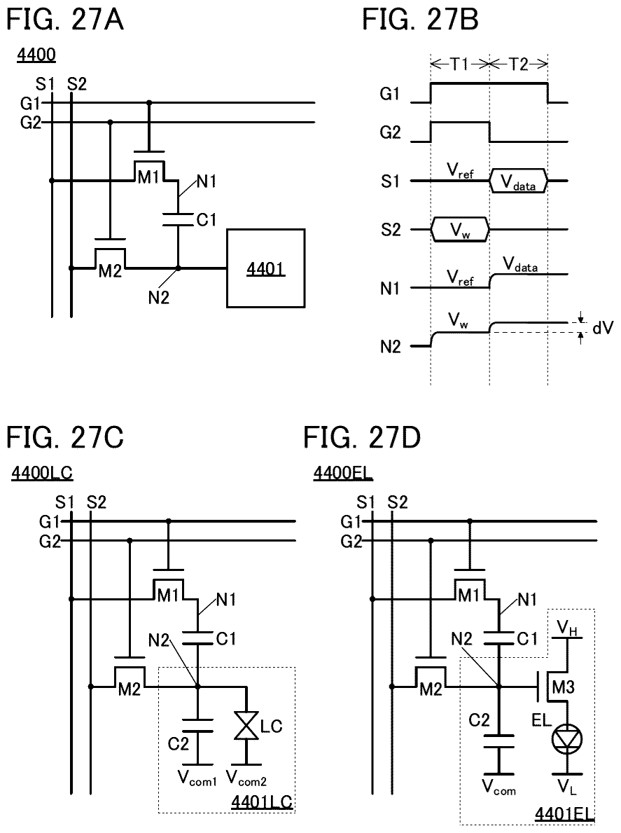

FIG. 27A is a circuit diagram of a pixel circuit 4400. The pixel circuit 4400 includes a transistor M1, a transistor M2, the capacitor C1, and a circuit 4401. A wiring S1, a wiring S2, a wiring G1, and a wiring G2 are connected to the pixel circuit 4400.

As the transistor M1 and the transistor M2, the vertical transistor of one embodiment of the present invention can be used.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 4401.

The circuit 4401 is a circuit including at least one display element. Here, a liquid crystal device is included as the display element. Note that without limitation to this, any of a variety of elements can be used as the display element; typically, a light-emitting element such as an organic EL element or an LED element, a MEMS (Micro Electro Mechanical Systems) element, or the like can be used.

A node connecting the transistor M1 and the capacitor C1 is denoted as a node N1, and a node connecting the transistor M2 and the circuit 4401 is denoted as a node N2.

In the pixel circuit 4400, the potential of the node N1 can be retained when the transistor M1 is turned off. The potential of the node N2 can be retained when the transistor M2 is turned off. When a predetermined potential is written to the node N1 through the transistor M1 with the transistor M2 being in an off state, the potential of the node N2 can be changed in accordance with displacement of the potential of the node N1 owing to capacitive coupling through the capacitor C1.

Here, the transistor using an oxide semiconductor, which is described in Embodiment 3, can be used as one or both of the transistor M1 and the transistor M2. Accordingly, owing to an extremely low off-state current, the potential of the node N1 or the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### Driving Method Example

Next, an example of a method for operating the pixel circuit 4400 is described with reference to FIG. 27B. FIG. 27B is a timing chart of the operation of the pixel circuit 4400. Note that for simplification of description, the influence of various kinds of resistance such as wiring resistance, parasitic capacitance, the threshold voltage of the transistor, and the like is not taken into account here.

In the operation shown in FIG. 27B, one frame period is divided into a period T1 and a period T2. The period T1 is a period in which a potential is written to the node N2, and the period T2 is a period in which a potential is written to the node N1.

### Period T1

In the period T1, a potential for turning on the transistor is supplied to both the wiring G1 and the wiring G2. In addition, a potential V_{ref} that is a fixed potential is supplied to the wiring S1, and a first data potential V_{w} is supplied to the wiring S2.

The potential V_{ref} is supplied from the wiring S1 to the node N1 through the transistor M1. The first data potential V_{w} is supplied from the wiring S2 to the node N2 through the transistor M2. Accordingly, a potential difference V_{w}−V_{ref} is retained in the capacitor C1.

### Period T2

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied from the wiring S1 to the node N1 through the transistor M1. At this time, capacitive coupling due to the capacitor C1 changes the potential of the node N2 in accordance with the second data potential V_{data} by a potential dV. That is, a potential that is the sum of the first data potential V_{w} and the potential dV is input to the circuit 4401. Note that although the potential dV is shown as a positive value in FIG. 27B, the potential dV may be a negative value. That is, the second data potential V_{data} may be lower than the potential V_{ref}.

Here, the potential dV is roughly determined by the capacitance value of the capacitor C1 and the capacitance value of the circuit 4401. When the capacitance value of the capacitor C1 is sufficiently larger than the capacitance value of the circuit 4401, the potential dV is a potential close to the second data potential V_{data}.

In the above manner, the pixel circuit 4400 can generate a potential to be supplied to the circuit 4401 including the display element, by combining two kinds of data signals; hence, a gray level can be corrected in the pixel circuit 4400.

The pixel circuit 4400 can also generate a potential exceeding the maximum potential that can be supplied by a source driver connected to the wiring S1 and the wiring S2. For example, in the case of using a light-emitting element, high-dynamic range (HDR) display or the like can be performed. Furthermore, in the case where a liquid crystal device is used, overdriving or the like can be achieved.

### Application Example

### Example Using Liquid Crystal Device

A pixel circuit 4400LC illustrated in FIG. 27C includes a circuit 4401LC. The circuit 4401LC includes a liquid crystal device LC and the capacitor C2.

In the liquid crystal device LC, one electrode is connected to the node N2 and one electrode of the capacitor C2, and the other electrode is connected to a wiring supplied with a potential V_{com2}. The other electrode of the capacitor C2 is connected to a wiring supplied with a potential V_{com1}.

The capacitor C2 functions as a storage capacitor. Note that the capacitor C2 can be omitted when not needed.

In the pixel circuit 4400LC, high voltage can be supplied to the liquid crystal device LC; thus, high-speed display can be performed by overdriving or a liquid crystal material with high drive voltage can be employed, for example. In addition, gray levels can also be corrected in accordance with operating temperature, the degradation state of the liquid crystal device LC, or the like by supply of a correction signal to the wiring S1 or the wiring S2.

### Example Using Light-Emitting Element

A pixel circuit 4400EL illustrated in FIG. 27D includes a circuit 4401EL. The circuit 4401EL includes a light-emitting element EL, a transistor M3, and the capacitor C2.

In the transistor M3, a gate is connected to the node N2 and one electrode of the capacitor C2, one of a source and a drain is connected to a wiring supplied with a potential V_{H}, and the other is connected to one electrode of the light-emitting element EL. The other electrode of the capacitor C2 is connected to a wiring supplied with a potential V_{com}. The other electrode of the light-emitting element EL is connected to a wiring supplied with a potential V_{L}.

The transistor M3 has a function of controlling current to be supplied to the light-emitting element EL. The capacitor C2 functions as a storage capacitor. The capacitor C2 can be omitted when not needed.

Note that although the structure in which the anode side of the light-emitting element EL is connected to the transistor M3 is described here, the transistor M3 may be connected to the cathode side. In that case, the values of the potential V_{H} and the potential V_{L} can be changed as appropriate.

In the pixel circuit 4400EL, a large amount of current can flow through the light-emitting element EL when a high potential is supplied to the gate of the transistor M3, which enables HDR display, for example. A variation in the electrical characteristics of the transistor M3, the light-emitting element EL, or the like can be corrected by supply of a correction signal to the wiring S1 or the wiring S2.

Note that the structure is not limited to the circuits illustrated in FIG. 27C and FIG. 27D, and a structure to which a transistor, a capacitor, or the like is further added may be employed.

At least part of this embodiment can be implemented in combination with any of the other embodiments described in this specification as appropriate.

### Embodiment 5

In this embodiment, a structure example of a touch panel module including a touch panel and an IC will be described.

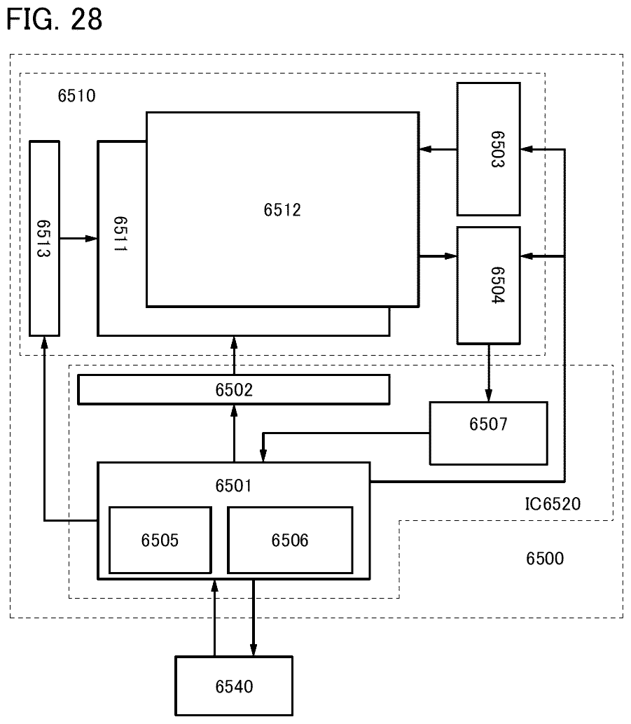

FIG. 28 shows a block diagram of a touch panel module 6500. The touch panel module 6500 includes a touch panel 6510 and an IC 6520.

The touch panel 6510 includes a display portion 6511, an input portion 6512, a scan line driver circuit 6513, a sensor driver circuit 6503, and a detection circuit 6504. The display portion 6511 includes a plurality of pixels, a plurality of signal lines, and a plurality of scan lines and has a function of displaying an image. The input portion 6512 includes a plurality of sensor elements for sensing the contact or approach of an object to the touch panel 6510 to have a function of a touch sensor. The scan line driver circuit 6513 has a function of outputting a scan signal to a scan line included in the display portion 6511.

The sensor driver circuit 6503 has a function of outputting a signal for driving a sensor element in the input portion 6512. As the sensor driver circuit 6503, a shift register circuit and a buffer circuit can be used in combination, for example.

The detection circuit 6504 has functions of amplifying an output signal from the sensor element included in the input portion 6512 and outputting it to an AD converter circuit 6507.

The display portion 6511 and the input portion 6512 are separately illustrated in the touch panel 6510 for simplicity; however, a so-called in-cell touch panel having both a function of displaying an image and a function of a touch sensor may be employed.

As a touch sensor that can be used for the input portion 6512, a capacitive touch sensor can be used. Examples of the capacitive touch sensor include a surface capacitive touch sensor and a projected capacitive touch sensor. Examples of the projected capacitive touch sensor include a self-capacitive touch sensor and a mutual capacitive touch sensor. The use of a mutual capacitive type is preferable because multiple points can be sensed simultaneously.

Note that without limitation to this, any of various sensors that can sense the approach, contact, or press of an object such as a finger or a stylus can be used as the input portion 6512. In addition to a capacitive type, a variety of types such as a resistive type, a surface acoustic wave type, an infrared type, and an optical type can be used as the sensor type, for example.

As typical examples of the in-cell touch panel, a hybrid in-cell type and a full-in-cell type can be given. The hybrid in-cell type refers to a structure in which an electrode or the like included in a touch sensor is provided over a substrate that supports a display element and a counter substrate or over the counter substrate. Meanwhile, a full-in-cell type refers to a structure in which an electrode or the like included in a touch sensor is provided over a substrate that supports a display element. In the case of a full-in-cell touch panel, a structure of a counter substrate can be simplified, which is preferable. In particular, when an electrode included in a display element also serves as an electrode in a touch sensor in a full-in-cell touch sensor, a manufacturing process can be simplified and manufacturing cost can be reduced, which is preferable.

The definition of the display portion 6511 is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. It is preferable that the pixel density (resolution) of the pixels in the display portion 6511 be higher than or equal to 300 ppi, preferably higher than or equal to 500 ppi, further preferably higher than or equal to 800 ppi, further preferably higher than or equal to 1000 ppi, further preferably higher than or equal to 1200 ppi. The display portion 6511 with such high definition and high resolution enables an increase in a realistic sensation, sense of depth, and the like.

The IC 6520 includes a circuit unit 6501, a signal line driver circuit 6502, and the AD converter circuit 6507. The circuit unit 6501 includes a timing controller 6505, an image processing circuit 6506, or the like.

The signal line driver circuit 6502 has a function of outputting an image signal (also referred to as a video signal) that is an analog signal to the signal lines included in the display portion 6511. For example, the signal line driver circuit 6502 can have a structure in which a shift register, a digital-analog convertor circuit (DAC), a latch circuit, a buffer circuit, and the like are combined. The touch panel 6510 may include a demultiplexer circuit connected to the signal line.

The AD converter circuit 6507 has a function of converting an analog signal input from the detection circuit 6504 to a digital signal and outputting the digital signal to the circuit unit 6501. The AD converter circuit 6507 can include an amplifier circuit in addition to an analog-digital convertor circuit (ADC), for example.

The image processing circuit 6506 included in the circuit unit 6501 has a function of generating and outputting a signal for driving the display portion 6511 of the touch panel 6510, a function of generating and outputting a signal for driving the input portion 6512, and a function of analyzing a signal output from the input portion 6512 and outputting the signal to a CPU 6540.

More specifically, the image processing circuit 6506 has a function of generating a video signal in accordance with an instruction from the CPU 6540, for example. Furthermore, the image processing circuit 6506 has a function of performing signal processing on an image signal in accordance with the specifications of the display portion 6511, converting the signal into an analog image signal, and supplying the analog image signal to the signal line driver circuit 6502. The image processing circuit 6506 has a function of generating a driver signal to be output to the sensor driver circuit 6503, in response to an instruction from the CPU 6540. The image processing circuit 6506 has a function of analyzing a signal input from the detection circuit 6504 through the AD converter circuit 6507 and outputting the signal to the CPU 6540 as positional information.

In addition, the timing controller 6505 has a function of generating a signal (a signal such as a clock signal or a start pulse signal) output to the scan line driver circuit 6513 and the sensor driver circuit 6503 on the basis of a synchronization signal included in a video signal or the like on which the image processing circuit 6506 performs processing. Furthermore, the timing controller 6505 may have a function of generating and outputting a signal for determining timing when the detection circuit 6504 outputs a signal. Here, the timing controller 6505 preferably outputs a signal synchronized with the signal output to the scan line driver circuit 6513 and a signal synchronized with the signal output to the sensor driver circuit 6503 of the optical sensor portion. In particular, it is preferable that a period in which data of a pixel in the display portion 6511 is rewritten and a period in which sensing is performed with the input portion 6512 be separately provided. For example, the touch panel 6510 can be driven by dividing one frame period into a period in which data of a pixel is rewritten and a period in which sensing is performed. Furthermore, detection sensitivity and detection accuracy can be increased, for example, by providing two or more sensing periods in one frame period.

The image processing circuit 6506 can have a structure including, for example, a processor. A microprocessor such as a DSP (Digital Signal Processor) or a GPU (Graphics Processing Unit) can be used, for example. A structure may be employed in which such a microprocessor is obtained with a PLD (Programmable Logic Device) such as an FPGA (Field Programmable Gate Array) or an FPAA (Field Programmable Analog Array). The image processing circuit 6506 interprets and executes instructions from various programs with the use of a processor to process various kinds of data, control programs, and the like. The programs that might be executed by the processor may be stored in a memory region included in the processor or a memory device which is additionally provided.

Note that for one or more of the display portion 6511, the input portion 6512, the scan line driver circuit 6513, the sensor driver circuit 6503, and the detection circuit 6504 included in the touch panel 6510, it is preferable to use a transistor which has an extremely low off-state current and in which an oxide semiconductor is used for a channel formation region. The transistor has an extremely low off-state current; therefore, with the use of the transistor as a switch for retaining electric charge (data) that flows into a capacitor element functioning as a storage element, a long data retention period can be ensured. The transistor may be used for the circuit unit 6501, the signal line driver circuit 6502, and the AD converter circuit 6507 included in the IC 6520 and the CPU 6540 or the like provided outside. For example, by utilizing the characteristic for a register, a cache memory, or the like of the image processing circuit 6506, what is called normally off computing is achieved where the image processing circuit 6506 operates only when needed, data on the immediately preceding processing is stored in the memory element in the rest of time, and power supply to the image processing circuit 6506 is stopped when the image processing circuit 6506 is not used; thus, power consumption of the touch panel module 6500 and an electronic device on which the touch panel module 6500 is mounted can be reduced.

Although the structure where the circuit unit 6501 includes the timing controller 6505 and the image processing circuit 6506 is employed here, the image processing circuit 6506 itself or a circuit having a function of part of the image processing circuit 6506 may be provided outside the IC 6520. Alternatively, the CPU 6540 may have a function of the image processing circuit 6506 or part thereof. For example, the circuit unit 6501 can include the signal line driver circuit 6502, the timing controller 6505, and the AD converter circuit 6507.

Although the example where the IC 6520 includes the circuit unit 6501 is shown here, the structure where the circuit unit 6501 is not included in the IC 6520 may be employed. In that case, the IC 6520 can include the signal line driver circuit 6502 and the AD converter circuit 6507. For example, in the case where the touch panel module 6500 includes a plurality of ICs, an IC including the circuit unit 6501 may be separately provided and a plurality of ICs 6520 without the circuit unit 6501 may be provided, and alternatively, the IC 6520 and an IC including only the signal line driver circuit 6502 can be provided in combination.

When an IC has a function of driving the display portion 6511 of the touch panel 6510 and a function of driving the input portion 6512 as described above, the number of ICs mounted on the touch panel module 6500 can be reduced; accordingly, cost can be reduced.

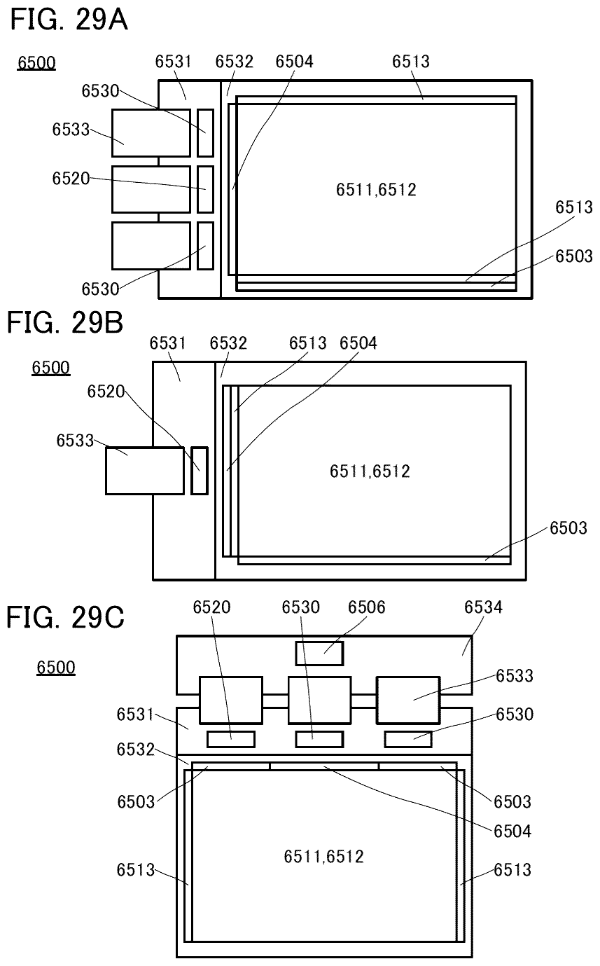

FIG. 29A, FIG. 29B, and FIG. 29C each are a schematic diagram of the touch panel module 6500 on which the IC 6520 is mounted.

In FIG. 29A, the touch panel module 6500 includes a substrate 6531, a counter substrate 6532, a plurality of FPCs 6533, the IC 6520, ICs 6530, and the like. The display portion 6511, the input portion 6512, the scan line driver circuits 6513, the sensor driver circuit 6503, and the detection circuit 6504 are provided between the substrate 6531 and the counter substrate 6532. The IC 6520 and the ICs 6530 are mounted on the substrate 6531 by a COG method.

The ICs 6530 are each an IC including only the signal line driver circuit 6502 or the signal line driver circuit 6502 and the circuit unit 6501 in the above-described IC 6520. The IC 6520 and the IC 6530 are supplied with a signal from the outside through the FPCs 6533. Furthermore, a signal can be output to the outside from the IC 6520 or the IC 6530 through the FPC 6533.

FIG. 29A illustrates an example where the display portion 6511 is sandwiched between two scan line driver circuits 6513. The ICs 6530 are provided in addition to the IC 6520. Such a structure is preferable in the case where the display portion 6511 has extremely high resolution.

FIG. 29B illustrates an example where one IC 6520 and one FPC 6533 are provided. It is preferable to bring functions into one IC 6520 in this manner because the number of components can be reduced. In the example in FIG. 29B, the scan line driver circuit 6513 is provided along a side close to the FPC 6533 among two short sides of the display portion 6511.

FIG. 29C illustrates an example of including a printed circuit board (PCB) 6534 on which the image processing circuit 6506 and the like are mounted. The IC 6520 and the ICs 6530 over the substrate 6531 are electrically connected to the PCB 6534 through the FPCs 6533. The above-described structure without the image processing circuit 6506 can be applied to the IC 6520.

In each of FIG. 29A, FIG. 29B, and FIG. 29C, the IC 6520 and the IC 6530 may be mounted on the FPC 6533, not on the substrate 6531. For example, the IC 6520 and the ICs 6530 can be mounted on the FPC 6533 by a packaging method such as a COF method, a TAB method, or the like.

A structure where the FPC 6533, the IC 6520 (and the ICs 6530), or the like is provided on a short side of the display portion 6511 as illustrated in FIG. 29A and FIG. 29B enables the frame of the display device to be narrowed; thus, the structure is preferably used for electronic devices such as smartphones, mobile phones, and tablet terminals, for example. The structure with the PCB 6534 illustrated in FIG. 29C can be preferably used for television devices, monitor devices, tablet terminals, or laptop personal computers, for example.

At least part of this embodiment can be implemented in combination with any of the other embodiments described in this specification as appropriate.

### Embodiment 6

In this embodiment, electronic devices of embodiments of the present invention will be described.

Electronic devices of this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

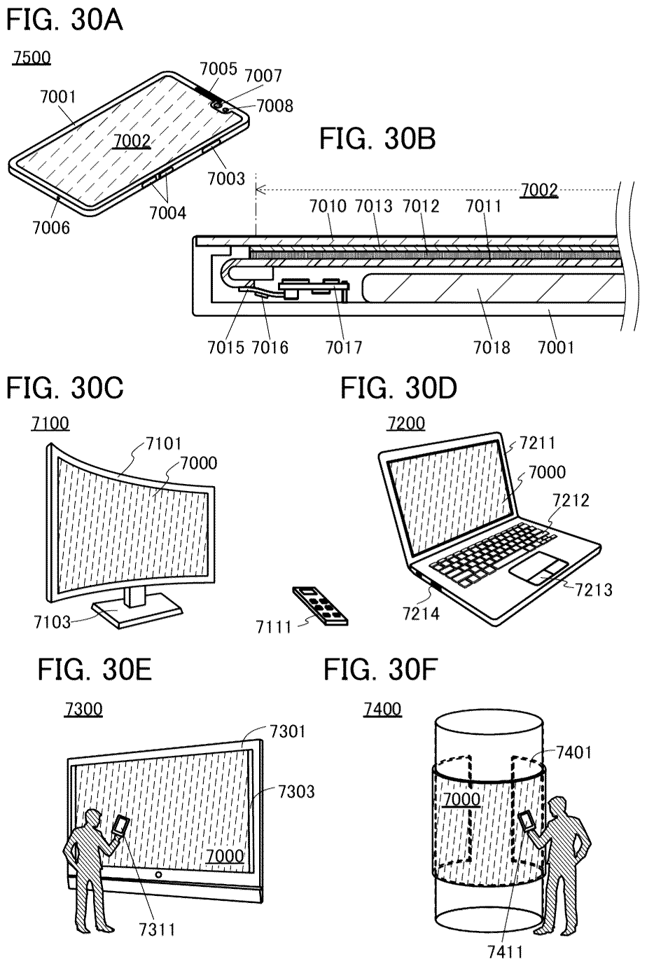

An electronic device 7500 illustrated in FIG. 30A is a portable information terminal device that can be used as a smartphone.

The electronic device 7500 includes a housing 7001, a display portion 7002, a power supply button 7003, buttons 7004, a speaker 7005, a microphone 7006, a camera 7007, a light source 7008, and the like. The display portion 7002 has a touch panel function.

The display device of one embodiment of the present invention can be used in the display portion 7002.

FIG. 30B is a schematic cross-sectional view including an end portion of the housing 7001 on the microphone 7006 side.

A protection member 7010 having a light-transmitting property is provided on the display surface side of the housing 7001. A display panel 7011, an optical member 7012, a touch sensor panel 7013, a printed circuit board 7017, a battery 7018, and the like are provided in a space surrounded by the housing 7001 and the protection member 7010.

The display panel 7011, the optical member 7012, and the touch sensor panel 7013 are fixed to the protection member 7010 with an adhesive layer (not illustrated).

Part of the display panel 7011 is folded back in a region outside the display portion 7002, and an FPC 7015 is connected to the part that is folded back. An IC 7016 is mounted on the FPC 7015. The FPC 7015 is connected to a terminal provided on the printed circuit board 7017.

The display device of one embodiment of the present invention can be used for the display panel 7011. In that case, an extremely lightweight electronic device can be obtained. Since the display panel 7011 is extremely thin, the battery 7018 with high capacity can be mounted without an increase in the thickness of the electronic device. Moreover, part of the display panel 7011 is folded back so that a connection portion with the FPC 7015 is provided on the back side of the pixel portion, whereby an electronic device with a narrow bezel can be obtained.

FIG. 30C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 30C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 30D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 30E and FIG. 30F illustrate examples of digital signage.

Digital signage 7300 illustrated in FIG. 30E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 30F is digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIG. 30E and FIG. 30F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 30E and FIG. 30F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

At least part of this embodiment can be implemented in combination with any of the other embodiments described in this specification as appropriate.

### REFERENCE NUMERALS

AF1: alignment film, AF2: alignment film, BM: light-blocking film, CF: coloring layer, DL_1: data line, DL_n: data line, DL_Y: data line, GL_1: gate line, GL_m: gate line, GL_X: gate line, KB: layer, LC: liquid crystal device, VL_a: potential supply line, VL_b: potential supply line, 10: transistor, 100: transistor, 104: electrode, 106: insulating layer, 108: semiconductor layer, 110_1: plane, 110_2: plane, 110_3: plane, 110_4: opening portion, 110A: layer, 110B: layer, 110C: layer, 112A: electrode, 112B: electrode, 112B_3: plane, 112B_4: opening portion, 153: substrate, 154: insulating layer, 155: conductive layer, 156: insulating layer, 157: insulating layer, 158: insulating layer, 159: opening, 160: conductive layer, 161: semiconductor layer, 162: insulating layer, 163: conductive layer, 164: insulating layer, 166: conductive layer, 510: functional layer, 516: layer, 517_4: opening, 517A: layer, 517B: layer, 517: layer, 518_4: opening portion, 518: layer, 519A: conductive layer, 519B: conductive layer, 519C: conductive layer, 520: functional layer, 521: layer, 522: layer, 550LC: liquid crystal device, 550: functional element, 551LC: electrode, 552LC: electrode, 553LC: layer, 4400EL: pixel circuit, 4400LC: pixel circuit, 4400: pixel circuit, 4401EL: circuit, 4401LC: circuit, 4401: circuit, 4501: pixel circuit, 4502: pixel portion, 4504a: gate driver, 4504b: source driver, 4504: driver circuit portion, 4506: protection circuit, 4507: terminal portion, 4550: transistor, 4552: transistor, 4554: transistor, 4560: capacitor element, 4562: capacitor element, 4570: liquid crystal device, 4572: light-emitting element, 5050A: display device, 5140: connection portion, 5151: substrate, 5152: substrate, 5162: display portion, 5164: circuit portion, 5165: wiring, 5172: FPC, 5173: IC, 5210B: subpixel, 5210G: subpixel, 5210R: subpixel, 5210: pixel, 6500: touch panel module, 6501: circuit unit, 6502: signal line driver circuit, 6503: sensor driver circuit, 6504: detection circuit, 6505: timing controller, 6506: image processing circuit, 6507: AD converter circuit, 6510: touch panel, 6511: display portion, 6512: input portion, 6513: scan line driver circuit, 6520: IC, 6530: IC, 6531: substrate, 6532: counter substrate, 6533: FPC, 6534: PCB, 6540: CPU, 7000: display portion, 7001: housing, 7002: display portion, 7003: power supply button, 7004: button, 7005: speaker, 7006: microphone, 7007: camera, 7008: light source, 7010: protection member, 7011: display panel, 7012: optical member, 7013: touch sensor panel, 7015: FPC, 7016: IC, 7017: printed circuit board, 7018: battery, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 7500: electronic device

1. A semiconductor device comprising:
a first functional layer;
a second functional layer; and
a first conductive layer,
wherein the second functional layer overlaps with the first functional layer,
wherein the second functional layer comprises a functional element,
wherein the functional element comprises a first electrode,
wherein the first functional layer comprises a first layer, a spacer, and a transistor,
wherein the first layer is sandwiched between the second functional layer and the spacer,
wherein the first layer comprises a first opening portion,
wherein the first layer has an insulating property,
wherein the spacer comprises a first plane, a second plane, a third plane, and a second opening portion,
wherein the first plane, the second plane, and the third plane each have an insulating property,
wherein the second plane faces the first plane,
wherein the second plane is positioned closer to the first layer than the first plane is,
wherein the third plane connects the first plane and the second plane to each other,
wherein the third plane is positioned at a side surface of the second opening portion,
wherein the transistor comprises a second electrode, a third electrode, a fourth electrode, a semiconductor layer, and an insulating layer,
wherein the second electrode comprises a region in contact with the first plane and a region overlapping with the second opening portion,
wherein the third electrode comprises a region in contact with the second plane, a third opening portion, and a fourth plane,
wherein the fourth plane is positioned at a side surface of the third opening portion,
wherein the third opening portion overlaps with the second opening portion,
wherein the fourth electrode comprises a region facing the third plane,
wherein the insulating layer comprises a region sandwiched between the third plane and the fourth electrode,
wherein the semiconductor layer comprises a region sandwiched between the third plane and the insulating layer,
wherein the semiconductor layer is in contact with the second electrode in the second opening portion,
wherein the semiconductor layer is in contact with the third electrode at the fourth plane, and
wherein the first conductive layer electrically connects the third electrode and the first electrode to each other through the first opening portion.

2. The semiconductor device according to claim 1, further comprising a second conductive layer,
wherein the second conductive layer is electrically connected to the second electrode,
wherein the second conductive layer has a light-blocking property, and
wherein the first opening portion overlaps with the second conductive layer.

3. The semiconductor device according to claim 2, further comprising a third conductive layer,
wherein the first functional layer comprises a second layer,
wherein the second layer is sandwiched between the first layer and the spacer,
wherein the second layer comprises a fourth opening portion,
wherein the second layer has an insulating property,
wherein the third conductive layer is sandwiched between the first layer and the second layer,
wherein the third conductive layer overlaps with the first opening portion and the fourth opening portion,
wherein the third conductive layer electrically connects the first conductive layer and the third electrode to each other,
wherein the third conductive layer has a light-transmitting property, and
wherein the third electrode has a light-transmitting property.

4. The semiconductor device according to claim 3,
wherein the first functional layer comprises a fourth conductive layer,
wherein the first layer is sandwiched between the fourth conductive layer and the third conductive layer, and
wherein the fourth conductive layer has a light-transmitting property.

5. The semiconductor device according to claim 1, further comprising a third conductive layer,
wherein the first functional layer comprises a second layer,
wherein the second layer is sandwiched between the first layer and the spacer,
wherein the second layer comprises a fourth opening portion,
wherein the second layer has an insulating property,
wherein the third conductive layer is sandwiched between the first layer and the second layer,
wherein the third conductive layer overlaps with the first opening portion and the fourth opening portion,
wherein the third conductive layer electrically connects the first conductive layer and the third electrode to each other,
wherein the third conductive layer has a light-transmitting property,
wherein the second electrode has a light-blocking property, and
wherein the first opening portion overlaps with the second electrode.

6. The semiconductor device according to claim 1, further comprising:
a third conductive layer, and
a fifth conductive layer,
wherein the first functional layer comprises a second layer,
wherein the second layer is sandwiched between the first layer and the spacer,
wherein the second layer comprises a fourth opening portion,
wherein the second layer has an insulating property,
wherein the third conductive layer is sandwiched between the first layer and the second layer,
wherein the third conductive layer overlaps with the first opening portion and the fourth opening portion,
wherein the third conductive layer electrically connects the first conductive layer and the third electrode to each other,
wherein the third conductive layer has a light-transmitting property,
wherein the fifth conductive layer is electrically connected to the fourth electrode,
wherein the fifth conductive layer overlaps with the first opening portion, and
wherein the fifth conductive layer has a light-blocking property.

7. A display device comprising the semiconductor device according to claim 1, wherein the functional element is a liquid crystal device.

8. A display module comprising:
the display device according to claim 7; and
at least one of a connector and an integrated circuit.

9. An electronic device comprising:
the display device according to claim 7; and
at least one of a battery, a camera, a speaker, and a microphone.
